(19) United States
(12) Patent Application Publication
(10) Pub. No.: US 2017/0330983 A1
(43) Pub. Date: Nov. 16, 2017

(54) Ferroelectric Perovskite Oxide-Based Photovoltaic Materials

(71) Applicants: Peter K. Davies, Newtown, PA (US); Andrew M. Rappe, Penn Valley, PA (US); Ilya Grinberg, Fairlawn, NJ (US); Jonathan E. Spanier, Bala Cynwyd, PA (US); Liyan Wu, Philadelphia, PA (US); Fenggong Wang, Rockville, MD (US); Andrei R. Akbasheu, Mountain View, CA (US)

(72) Inventors: Peter K. Davies, Newtown, PA (US); Andrew M. Rappe, Penn Valley, PA (US); Ilya Grinberg, Fairlawn, NJ (US); Jonathan E. Spanier, Bala Cynwyd, PA (US); Liyan Wu, Philadelphia, PA (US); Fenggong Wang, Rockville, MD (US); Andrei R. Akbasheu, Mountain View, CA (US)

(21) Appl. No.: 15/370,602

(22) Filed: Dec. 6, 2016

Related U.S. Application Data
(60) Provisional application No. 62/264,108, filed on Dec. 7, 2015.

(51) Int. Cl. H01L 31/032; C04B 35/462; H01L 31/072; H01L 31/18

(52) U.S. Cl. CPC H01L 31/032; H01L 31/18; C04B 35/462; H01L 31/072

(57) ABSTRACT

A ferroelectric perovskite composition, comprising a perovskite oxide ABO₃, and a doping agent selected from perovskites of Ba(Ni,Nb)O₃ and Ba(Ni,Nb)O_{3-δ}. The ferroelectric perovskite composition may be represented by the formula: xBa(Ni,Nb)O₃.(1-x)ABO₃ or xBa(Ni,Nb)O_{3-δ}.(1-x)ABO_{3.} A method of producing the ferroelectric perovskite composition in thin film form is also provided.

### RELATED APPLICATION DATA

This application claims the benefit of U.S. Provisional Application No. 62/264,108, filed on Dec. 7, 2015, the entire disclosure of which is hereby incorporated by reference as if set forth fully herein.

### STATEMENT OF GOVERNMENT INTEREST

This invention was made with government support under Contract No. W911NF-08-1-0067 awarded by the Army Research Office, Contract No. DE-FG02-07ER46431 awarded by the Department of Energy, and Contract No. N00014-12-1-1033 awarded by the Office of Naval Research. The government has certain rights in the invention.

### BACKGROUND OF THE INVENTION

### 1. Field of the Invention

The present invention is generally related to the field of ferroelectric photovoltaic materials. In particular the present invention is related to a perovskite oxide-based ferroelectric photovoltaic materials and method for making the same.

### 2. Description of the Related Technology

Renewable energy sources are becoming an important part of national energy strategy. One such promising energy source is solar energy. In search for new technologies for harvesting solar energy, much attention is focused on development of new environmentally-friendly and chemically stable photovoltaic materials with desired functional properties. These functional properties include the ability to absorb light in the whole UV and visible spectral range, having a small band gap of less than 2.5 eV, and providing efficient solar energy conversion.

In conventional solar cells, photo-excited charge carriers are separated by the electric field at a p-n junction, which sets an upper bound of the power conversion efficiency (Shockley, et al., “Detailed balance limit of efficiency of p-n junction solar cells,” J. Appl. Phys. vol. 32, pp. 510-519, 1961). Currently, the most popular photovoltaic materials used in photovoltaic cells are bulk single-crystalline silicon-based materials that must be used with dopant atoms. Since silicon is an indirect band-gap substance, the thickness of the single-crystalline silicon is required to be approximately 100 times larger than photovoltaic materials using a direct band-gap substance in order to achieve comparable absorption over a similar solar spectrum. Further the process for making photovoltaic cells using these silicon-based photovoltaic materials requires formation of a p-n junction, or interface between two different regions having different doping. The solar energy conversion efficiency for the silicon-based photovoltaic materials is thus less than optimal.

Another type of photovoltaic material is a photovoltaic thin-film produced from CdTe, CuInGaSe (CIGS) or the like. These photovoltaic materials are attractive because they are direct band gap materials. However these photovoltaic materials are relatively expensive compared with silicon-based materials and also require formation of a p-n junction. Further, some of the components used to make these photovoltaic materials, such as Cd, are known to be toxic.

Ferroelectric (FE) materials, possessing an intrinsic spontaneous, switchable polarization, are promising for photovoltaic solar energy conversion because photo-excited charge carriers can be separated by an interfacial electric field or by bulk photovoltaic effects due to inversion symmetry breaking, enabling photovoltages that can exceed the band gap (Grekov, et al., “Photoelectric effects in A5B6C7-type ferroelectrics-semiconductors with low-temperature phase transitions,” Kristallografiya vol. 15, pp. 500-509, 1970; Glass, et al., “High-voltage bulk photovoltaic effect and the photorefractive process in LiNbO3,” Appl Phys Lett vol. 25, pp. 233-235, 1974). In addition, the photo-excited carriers can be collected prior to cooling (Sturman, et al., “The Photovoltaic and Photorefractive Effects in Noncentrosymmetric Materials,” Gordon and Breach Science Publishers, 1992; Fridkin et al., “Parity nonconservation and bulk photovoltaic effect in a crystal without symmetry center,” IEEE Trans. Ultrason., Ferroelect., Freq Cont. vol. 60, pp. 1551-1555, 2013), permitting a power conversion efficiency that is greater than the band gap-specific Shockley-Queisser limit (Spanier et al., “Power conversion efficiency exceeding the Shockley-Queisser limit in a ferroelectric insulator,” Nat Photon vol. 10, pp. 611-616, 2016).

These FE materials are very promising photovoltaic materials, which are cheaper to make and more efficient in harvesting solar energy. However, currently known FE materials have some drawbacks. The non-centrosymmetric crystal structure of the FE materials breaks the symmetry of the momentum distribution for non-equilibrium. The optically-generated current flows in one direction in the FE materials, resulting in bulk photovoltaic effect (BPVE). Equally significant, the internal electric field of the FE materials caused by a depolarization field can easily separate light-generated excitons. Finally, FE materials have domain walls that result in gradients in FE polarization, and therefore electrostatic potential. Also the poor light absorption and large band gap (˜3 eV) of many FE materials may lead to a low quantum efficiency of photovoltaic cells made therefrom.

Until now, there are only a few FE materials that may be suitable for making photovoltaic cells on a commercial scale. The most promising FE materials are based on BiFeO₃ with a band gap of ˜2.7 eV. However, BiFeO₃ in the form of a thin film state has an external quantum efficiency (EQE) above 2% only for photons with a wavelength of less than 450 nm. Thus, these FE materials do not absorb most of the solar energy in the visible spectral region resulting in a solar energy conversion efficiency that is still less than optimal.

Recently, a new type of FE material (1-x)KNbO₃-xBaNb_{0.5}Ni_{0.5}O₃ (KBNNO) has been developed. KBNNO has a band gap that depends on the value of x. The smallest band gap for this FE material is about 1.4 eV when x=0.1. This is relatively close to the band gaps of the GaAs, Si, CdTe and CIGS photovoltaic materials that are currently used in some modern solar cell technologies.

KBNNO has been made into thin films that can narrow the band gap to between 1.0 eV and 3.8 eV, thereby enhancing their applicability in photovoltaic cells. These KBNNO thin films have a thickness of 15 nm to 1 micron, measured from the surface of the thin film facing the surface of a substrate on which it may be grown to the surface of the thin film facing outwards. The deposited material used to grow the thin film need not be planar, but can be nanostructured, e.g. can be in the form of a conformally coated layer.

A way of reducing the band gap in an FE material has been reported for BiFeO₃, which is one of the few ferroelectrics with a band gap within the visible spectrum (≈2.7 eV, Ihlefeld et al., “Optical bandgap of BiFeO₃ grown by molecular beam epitaxy,” Appl. Phys. Lett. 92, 2008). The band gaps of oxide ferroelectrics may be changed through specific chemical substitutions (Bennett et al., “New Highly Polar Semiconductor Ferroelectrics through d⁸ Cation-O Vacancy Substitution into PbTiO₃: A Theoretical Study,” J. Amer Ceram. Soc., vol. 130, pp. 17409-17412, 2008; Qi et al., ‘First-principles study of band gap engineering via oxygen vacancy doping in perovskite ABB′O₃ solid solutions,’ Phys. Rev. B vol. 84, p. 245206, 2011; Qi et al., “Band-gap engineering via local environment in complex oxides,” Phys Rev B, vol. 83, p. 224108, 2011). This has been reported for LaCoO₃-doped Bi₄Ti₃O₁₂ (Choi et al., “Wide bandgap tunability in complex transition metal oxides by site-specific substitution,” Nat Commun., vol. 3, p. 689, 2012), cation-ordered Bi(FeCo)O₃ (Nechache et al., “Bandgap tuning of multiferroic oxide solar cells,” Nat Photon vol. 9, pp. 61-67, 2014), KBiFe₂O₅ (Zhang et al., “New high Tc multiferroics KBiFe2O5 with narrow band gap and promising photovoltaic effect,” Sci. Rep., vol. 3, p. 1265, 2013) and BaNi_{0.5}Nb_{0.5}O_{3-δ}-doped KNbO₃ (KBNNO) systems (Grinberg et al., “Perovskite oxides for visible-light-absorbing ferroelectric and photovoltaic materials,” Nature, vol. 503, pp. 509-512, 2013). In the last case, the lowering of the band gap was achieved by introducing a combination of a lower valence Ni²⁺ acceptor and an oxygen vacancy V_{O}.

FE materials with an increased polarization and reduced band gap can generate larger open-circuit photovoltages along the polarization direction. Such FE materials have higher power conversion efficiency, thus making photovoltaic cells employing these materials more efficient. The enhancement of the FE polarization may be achieved via in-plane strain caused by epitaxial growth of the FE materials on a lattice-mismatched substrate. It has been discovered that epitaxial growth of FE materials such as KBNNO on a lattice-mismatched substrate can improve the photovoltaic properties of the resultant thin film.

The present invention provides improved FE photovoltaic materials and thin films with a low band gap and a broad-spectrum absorption down to 1 eV, as well as strong ferroelectric properties at room temperature. A method of epitaxial growth of the FE photovoltaic thin film is also provided that provides a thin film useful as an epitaxial semiconductor ferroelectric layer in photovoltaic heterostructures and superlattices, or as a substitute for the ferroelectric BaTiO₃ layer in optical devices.

### SUMMARY OF THE INVENTION

In one embodiment, the present invention provides a ferroelectric perovskite composition comprising a perovskite oxide ABO₃ and a doping agent selected from perovskites of Ba(Ni,Nb)O₃ and Ba(Ni,Nb)O_{3-δ} wherein δ is in a range of from 0 to 0.1.

In the foregoing embodiment, the ferroelectric perovskite composition may be represented by the formula: xBa(Ni,Nb)O₃.(1-x)ABO₃ or xBa(Ni,Nb)O_{3-δ}.(1-x)ABO₃ wherein x is from greater than 0 to less than 1.

The ferroelectric perovskite composition of any of the previous embodiments, may have x is in a range from about 0.01 to about 0.5, or from about 0.05 to about 0.45, or from about 0.10 to about 0.40, or from about 0.10 to about 0.35, or from about 0.15 to about 0.35, or from about 0.15 to about 0.30, or from about 0.20 to about 0.30.

The ferroelectric perovskite composition of any one of the previous embodiments wherein the ABO₃ perovskite oxide may include a perovskite selected from BaTiO₃.

The ferroelectric perovskite composition of any one of the previous embodiments wherein BaTiO₃ is the ABO₃ perovskite oxide.

The ferroelectric perovskite composition of any one of the previous embodiments, may have an atomic content of Ni in a range from about 0.005% to about 0.1%, or from about 0.01% to about 0.095%, or from about 0.015% to about 0.090%, or from about 0.020% to about 0.085%, or from about 0.025% to about 0.080%, or from about 0.030% to about 0.075%, or from about 0.035% to about 0.070%, or from about 0.040% to about 0.065%, or from about 0.045% to about 0.060%, or from about 0.050% to about 0.060%.

The ferroelectric perovskite composition of any one of the previous embodiments, may have δ is in a range of from about 0 to about 0.1, or from about 0.01 to about 0.09, or from about 0.02 to about 0.08, or from about 0.03 to about 0.07, or from about 0.04 to about 0.06.

The ferroelectric perovskite composition of any one of the previous embodiments, may have a band gap in a range of from about 0.8 eV to about 3.1 eV, or from about 1.0 eV to about 2.9 eV, or from about 1.2 eV to about 2.7 eV, or from about 1.4 eV to about 2.5 eV, or from about 1.4 eV to about 2.3 eV, or from about 1.6 eV to about 2.3 eV, or from about 1.6 eV to about 2.1 eV, or from about 1.8 eV to about 2.1 eV.

The ferroelectric perovskite composition of any one of the previous embodiments, may exhibit a measurable absorption of greater than about 104 cm⁻¹, or greater than about 106 cm⁻¹, or greater than about 108 cm⁻¹, or greater than about 110 cm⁻¹, or greater than about 112 cm⁻¹, or greater than about 114 cm⁻¹, or greater than about 116 cm⁻¹, or greater than about 118 cm⁻¹, or greater than about 120 cm⁻¹, or greater than about 122 cm⁻¹, or greater than about 124 cm⁻¹, or greater than about 126 cm⁻¹, throughout the entire visible wavelength spectrum.

The ferroelectric perovskite composition of any one of the previous embodiments, may exhibit a ferroelectric switching in a temperature up to about 400 K, or up to about 380 K, or up to about 350 K, or up to about 330 K, or up to about 300 K, or up to about 298 K, or up to about 296 K, or up to about 294 K, or up to about 292 K, or up to about 290 K, or up to about 288 K, or up to about 286 K, or up to about 284 K, or up to about 282 K, or up to about 280 K, or up to about 278 K, or up to about 276 K, or up to about 275 K.

The ferroelectric perovskite composition of any one of the previous embodiments, may exhibit a photovoltaic effect with a measurable, non-zero open-circuit voltage and a measurable, non-zero short-circuit current.

The ferroelectric perovskite composition of any one of the previous embodiments, may exhibit a ferroelectric photovoltaic effect.

The ferroelectric perovskite composition of the previous embodiment, wherein the ferroelectric photovoltaic effect is represented by reversing the polarity of current of the photovoltaic effect after electrical poling in the opposite film plane-normal direction.

The ferroelectric perovskite composition of any of the previous embodiments may be in a form selected from ceramic, crystalline, and film.

The ferroelectric perovskite composition of any of the previous embodiments, may be in a film form with a thickness in a range of from about 1 nm to about 10,000 nm, or from about 5 nm to about 9,000 nm, or from about 10 nm to about 8,000 nm, or from about 15 nm to about 7,000 nm, or from about 20 nm to about 6,000 nm, or from about 25 nm to about 5,000 nm, or from about 30 nm to about 4,000 nm, or from about 35 nm to about 3,000 nm, or from about 40 nm to about 2,000 nm, or from about 45 nm to about 1,000 nm, or from about 50 nm to about 900 nm, or from about 55 nm to about 850 nm, or from about 60 nm to about 800 nm, or from about 65 nm to about 750 nm, or from about 70 nm to about 700 nm, or from about 75 nm to about 650 nm, or from about 80 nm to about 600 nm, or from about 85 nm to about 550 nm, or from about 90 nm to about 500 nm, or from about 95 nm to about 450 nm, or from about 100 nm to about 400 nm.

The ferroelectric perovskite composition of any of the previous embodiments, may be in the form of a film produced by a method selected from physical vapor deposition, chemical vapor deposition, metal organic chemical vapor phase deposition, atomic layer deposition, and a sol-gel process.

In another embodiment, the present invention provides a method of making a ferroelectric thin film for a photoelectric device including steps of vaporizing a target, and growing a thin film from the vaporized target on a surface of a substrate. The grown thin film includes a perovskite oxide ABO₃; and a doping agent selected from perovskites of Ba(Ni,Nb)O₃ and Ba(Ni,Nb)O_{3-δ} wherein δ is in a range of from 0 to 0.1.

In the method of the previous embodiment, the composition of the film may be represented by the formula: xBa(Ni,Nb)O₃.(1-x)ABO₃ or xBa(Ni,Nb)O_{3-δ}.(1-x)ABO₃.

In the method of any of the previous embodiments, the thin film may have a thickness in a range of from about 15 nm to about 1 micron, or from about 30 nm to about 900 nm, or from about 50 nm to about 800 nm, from about 70 nm to about 700 nm, or from about 80 nm to about 600 nm, or from about 100 nm to about 500 nm.

In the method of any of the previous embodiments, the substrate may have a temperature in a range of from about 400 to about 800° C. during the growing step, or from about 420 to about 780° C., or from about 440 to about 760° C., or from about 460 to about 740° C., or from about 480 to about 720° C., or from about 500 to about 700° C., or from about 520 to about 680° C., or from about 540 to about 660° C., or from about 560 to about 640° C., or from about 580 to about 620° C., or from about 590 to about 610° C.

In the method of any of the previous embodiments, the substrate may be lattice mismatched with respect to the grown thin film.

In the method of any of the previous embodiments, the vaporizing step may be performed using a laser.

In the method of any of the previous embodiments, the vaporizing step may be performed using RF sputtering.

In the method of any f the previous embodiments, the substrate may be surrounded by a pressure in a range of from about 0.1 mTorr to about 75 mTorr, or from about 0.5 mTorr to about 70 mTorr, or from about 1.0 mTorr to about 70 mTorr, or from about 2 mTorr to about 65 mTorr, or from about 3 mTorr to about 65 mTorr, or from about 5 mTorr to about 65 mTorr, or from about 5 mTorr to about 60 mTorr, or from about 7 mTorr to about 60 mTorr, or from about 10 mTorr to about 60 mTorr, or from about 10 mTorr to about 55 mTorr, or from about 12 mTorr to about 55 mTorr, or from about 15 mTorr to about 55 mTorr.

In the method of any of the previous embodiments, the substrate may include a material selected from the group consisting of SrTiO₃, glass (SiO₂/Si(100)), DyScO3, (La,Sr)(Al,Ta)O₃, MgO, ZrO₂, electrically conductive perovskite, metallic perovskite, Nb-doped SrTiO₃, electrically conductive film, metallic films, SrRuO₃, LaNiO₃ and non-perovskite oxides.

In a further embodiment, the present invention provides a photovoltaic cell including the ferroelectric perovskite composition of any of the previous embodiments.

In the photovoltaic cell of the previous embodiment, the ferroelectric perovskite composition may be a thin film, having a thickness in a range of from about 15 nm to about 1 micron, or from about 30 nm to about 900 nm, or from about 50 nm to about 800 nm, from about 70 nm to about 700 nm, or from about 80 nm to about 600 nm, or from about 100 nm to about 500 nm.

### BRIEF DESCRIPTION OF THE DRAWINGS

FIG. 1A shows calculated band gaps for a ferroelectric photovoltaic material (1-x)BaTiO₃-(x)Ba(Ni_{1/2}Nb_{1/2})O_{2.75} when x=0.125 according to one embodiment of the present invention.

FIG. 1B shows calculated band gaps for the ferroelectric photovoltaic material (1-x)BaTiO₃-(x)Ba(Ni_{1/2}Nb_{1/2})O_{2.75} when x=0.33 according to one embodiment of the present invention.

FIG. 1C shows densities of states (DOS) for the ferroelectric photovoltaic material (1-x)BaTiO₃-(x)Ba(Ni_{0.5}Nb_{0.5})O_{2.75} when x=0.1 according to one embodiment of the present invention.

FIG. 1D shows calculated Tauc plots for ferroelectric photovoltaic materials KBNNO, (0.9)(BaTiO₃)-(0.1)(BaNi_{0.5}Nb_{0.5}O_{2.75}) (BTNNO) and KNbO₃ (KNO).

FIG. 2A shows X-ray diffraction patterns of BaTiO₃ with substitutions of Ni²⁺ and Nb⁵⁺ (BNN-substituted BaTiO₃) with different nominal oxygen vacancy concentrations.

FIG. 2B shows the ultraviolet-visible (UV-Vis) spectrum of BNN-substituted BaTiO₃.

FIG. 2C shows the Kubelka-Munk transformed UV-Vis absorption spectra of BTNNO.

FIG. 3A shows an X-ray diffraction pattern (2θ/ω-scan) of a BTNNO film on a (001) SrTiO₃ substrate.

FIG. 3B shows a reciprocal space map (RSM) of the BTNNO film on (001) SrTiO₃ substrate of FIG. 3A.

FIG. 3C shows a cross-section of an image taken by transmission electron microscopy (TEM) of the BTNNO/LSMO interface, where LSMO is lanthanum strontium manganite with a general formula La₁₋ₓSrₓMnO₃.

FIG. 3D shows an x-ray photoemission spectroscopy (XPS) spectrum of the Ni 2p3/2 states revealing the presence of both Ni²⁺ and Ni³⁺.

FIG. 3E shows an XPS spectrum indicating the valence electronic states of the BTNNO film on a conducting Nb:SrTiO₃ substrate.

FIG. 3F shows an XPS spectrum near the Fermi level (background-subtracted) with approximated band values.

FIG. 4 is a transmission electron microscopy image of a BTNNO film grown on a La₀.₇Sr_{0.3}MnO₃/SrTiO₃(001) substrate.

FIG. 5 shows XPS spectra of a BTNNO film on a conducting (001) Nb:SrTiO₃ substrate.

FIG. 6 shows an energy-dispersive X-ray spectrum for the BTNNO film.

FIG. 7 shows absorption coefficients of a bulk BTNNO material as compared to a silicon-based photovoltaic material.

FIG. 8A shows a schematic design of different electrode geometries used in ferroelectric polarization and photovoltaic measurements. The top contact edge-to-edge separation is about 30 μm.

FIG. 8B shows the ferroelectric polarization-voltages of a BTNNO film collected at different temperatures using a “top-top” geometry for the film of FIG. 8A.

FIG. 8C shows the capacitance-voltage response of a BTNNO film at 10 kHz using the same “top-top” geometry as in FIG. 8B.

FIG. 9A is a plot showing ferroelectric switching in BTNNO films of about 80 nm thickness deposited on a La₀.₇Sr_{0.3}MnO₃/SrTiO₃ (LSMO/STO) substrate at different temperatures.

FIG. 9B is a plot showing ferroelectric switching in BTNNO films of about 130 nm thickness deposited on a LSMO/STO substrate at different temperatures.

FIG. 9C is a plot showing the time dependence of the short-circuit photovoltaic current collected using a BTNNO film of 130 nm thickness with laser illumination at a 532 nm wavelength and an intensity of 240 mW/cm² after poling with a +25 V pulse using the “top-top” geometry. The light was turned on at about 50 seconds (marked as “ON” on the plot).

FIG. 9D shows the dependency of photovoltaic current on applied electric field in the BTNNO film of 130 nm thickness under illumination at a wavelength of 405 nm, with intensities ranging up to 200 mW/cm².

FIG. 9E is a plot showing linear variations of short-circuit current at different intensities.

FIG. 9F shows convergence of photovoltaic current at a common photovoltaic field.

FIG. 10 is a plot showing ferroelectric switching of photocurrent, collected using the “top-top” geometry.

FIG. 11A shows ferroelectric switching of the BTNNO film of a thickness of 130 nm in a double-pad geometry with a film produced using pulsed-laser deposition (PLD).

FIG. 11B shows ferroelectric switching of the BTNNO film having a thickness of 130 nm in a double-pad geometry with a film produced using PLD after a long period of storage of about 7-8 months.

FIG. 12 shows a cross-sectional scanning electron microscope (SEM) image of a 160 nm thick BaTiO₃-based film.

FIG. 13A is a plot showing the time dependence of the current collected after the BaTiO₃-based film (320 nm of the total thickness measured) was poled by a +25 V pulse. The laser (532 nm wavelength and 0.6 W/cm² intensity) was turned on at about 80 seconds.

FIG. 13B is a plot showing I-V characteristics of the film of FIG. 13A measured under illumination (colored curves) and in the dark (black curves).

FIG. 13C shows an enlarged part of the I-V curve with open-circuit voltage and short-circuit current.

FIG. 14A shows photovoltaic current-voltage traces measured in a 130 nm thick BTNNO film using a “top-bottom” geometry under 476 nm wavelength illumination at different intensities.

FIG. 14B shows the linear variation of photovoltaic current of the BTNNO film of FIG. 14A with incident intensity.

FIG. 15 is a flow chart showing one process for making ferroelectric photovoltaic materials according to one embodiment of the present invention.

### DETAILED DESCRIPTION OF THE PREFERRED EMBODIMENT(S)

For illustrative purposes, the principles of the present disclosure are described by referencing various exemplary embodiments. Although certain embodiments are specifically described herein, one of ordinary skill in the art will readily recognize that the same principles are equally applicable to, and can be employed in other systems and methods.

Before explaining the disclosed embodiments of the present disclosure in detail, it is to be understood that the disclosure is not limited in its application to the details of any particular embodiment shown. Additionally, the terminology used herein is for the purpose of description and not of limitation. Furthermore, although certain methods are described with reference to steps that are presented herein in a certain order, in many instances, these steps may be performed in any order as may be appreciated by one skilled in the art; the novel methods are therefore not limited to the particular arrangement of steps disclosed herein.

It must be noted that as used herein and in the appended claims, the singular forms “a”, “an”, and “the” include plural references unless the context clearly dictates otherwise. Furthermore, the terms “a” (or “an”), “one or more” and “at least one” can be used interchangeably herein. The terms “comprising”, “including”, “having” and “constructed from” can also be used interchangeably.

Unless otherwise indicated, all numbers expressing quantities of ingredients, properties such as molecular weight, percent, ratio, reaction conditions, and so forth used in the specification and claims are to be understood as being modified in all instances by the term “about,” whether or not the term “about” is present. Accordingly, unless indicated to the contrary, the numerical parameters set forth in the specification and claims are approximations that may vary depending upon the desired properties sought to be obtained by the present disclosure. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements.

It is to be understood that each component, compound, substituent or parameter disclosed herein is to be interpreted as being disclosed for use alone or in combination with one or more of each and every other component, compound, substituent or parameter disclosed herein.

It is also to be understood that each amount/value or range of amounts/values for each component, compound, substituent or parameter disclosed herein is to be interpreted as also being disclosed in combination with each amount/value or range of amounts/values disclosed for any other component(s), compounds(s), substituent(s) or parameter(s) disclosed herein and that any combination of amounts/values or ranges of amounts/values for two or more component(s), compounds(s), substituent(s) or parameters disclosed herein are thus also disclosed in combination with each other for the purposes of this description.

It is further understood that each range disclosed herein is to be interpreted as a disclosure of each specific value within the disclosed range that has the same number of significant digits. Thus, a range of from 1-4 is to be interpreted as an express disclosure of the values 1, 2, 3 and 4. It is further understood that each lower limit of each range disclosed herein is to be interpreted as disclosed in combination with each upper limit of each range and each specific value within each range disclosed herein for the same component, compounds, substituent or parameter. Thus, this disclosure to be interpreted as a disclosure of all ranges derived by combining each lower limit of each range with each upper limit of each range or with each specific value within each range, or by combining each upper limit of each range with each specific value within each range.

Furthermore, specific amounts/values of a component, compound, substituent or parameter disclosed in the description or an example is to be interpreted as a disclosure of either a lower or an upper limit of a range and thus can be combined with any other lower or upper limit of a range or specific amount/value for the same component, compound, substituent or parameter disclosed elsewhere in the application to form a range for that component, compound, substituent or parameter,

All documents mentioned herein are hereby incorporated by reference in their entirety or alternatively to provide the disclosure for which they were specifically relied upon. The applicant(s) do not intend to dedicate any disclosed embodiments to the public, and to the extent any disclosed modifications or alterations may not literally fall within the scope of the claims, they are considered to be part hereof under the doctrine of equivalents.

In one aspect, the present invention provides a ferroelectric perovskite composition. The composition comprises a perovskite oxide ABO₃ and a doping agent selected from perovskites of Ba(Ni,Nb)O₃ and Ba(Ni,Nb)O_{3-δ}, where δ is preferably in a range of from about 0 to about 0.1, or from about 0.01 to about 0.09, or from about 0.02 to about 0.08, or from about 0.03 to about 0.07, or from about 0.04 to about 0.06 or about 0.05. In one embodiment, the composition is preferably represented by the formula: xBa(Ni,Nb)O₃.(1-x)ABO₃ or xBa(Ni,Nb)O_{3-δ.(}1-x)ABO₃. The value of x is preferably in the range of from about 0.01 to about 0.5, or from about 0.05 to about 0.45, or from about 0.10 to about 0.40, or from about 0.10 to about 0.35, or from about 0.15 to about 0.35, or from about 0.15 to about 0.30, or from about 0.20 to about 0.30 and δ is as defined above.

In some embodiments, the ABO₃ perovskite oxide in the ferroelectric perovskite composition may include BaTiO₃. More preferably, the ABO₃ perovskite oxide is BaTiO₃.

In some embodiments, the ferroelectric perovskite composition preferably has an atomic content of Ni in a range from about 0.005% to about 0.1%, or from about 0.01% to about 0.095%, or from about 0.015% to about 0.090%, or from about 0.020% to about 0.085%, or from about 0.025% to about 0.080%, or from about 0.030% to about 0.075%, or from about 0.035% to about 0.070%, or from about 0.040% to about 0.065%, or from about 0.045% to about 0.060%, or from about 0.050% to about 0.060%.

In a more preferred embodiments, the BaTiO₃ is for two reasons. One is that the raw material cost of BaTiO₃ is an order of magnitude less expensive than that of KNbO₃. The other is that ferroelectric materials based on BaTiO₃ are capable of absorption of visible-light, which is highly advantageous for applications in photovoltaic devices.

To avoid the problematic instability of a high concentration of five-fold coordinated Ti atoms, both Ni²⁺ and Nb⁵⁺ are substituted onto the BaTiO₃ B-site. For a simple Ni²⁺-V_{O}\ddot{} substitution into BaTiO₃, each substitution of Ti⁴⁺ by Ni²⁺ creates two holes that are compensated by V_{O}\ddot{} that must be located between the Ni²⁺ and Ti⁴⁺ ions. On the other hand, the substitution of two Ti⁴⁺ ions by a Ni²⁺ and Nb⁵⁺ pair creates only one hole. Therefore, a single V_{O}\ddot{} must be created for two Ni²⁺+Nb⁵⁺ substituent pairs. This enables the vacancy compensating the charge imbalance to be located between two Ni ions only, avoiding the unfavorable 5-fold coordination of Ti. Thus, this Ni²⁺-V_{O}\ddot{} strategy may be used to obtain an improved ferroelectric photovoltaic material based on BaTiO₃.

In some embodiments, the ferroelectric perovskite composition preferably comprises BaTiO₃ coupled with substitution of Ni²⁺ and Nb⁵⁺, namely, a barium nickel niobate (BNN) composition. The ferroelectric perovskite composition is herein referred to as a BNN-substituted BaTiO₃ ceramic, which may be represented as:
1. “BNN”: (1-y)Ba(Ni_{1/3}Nb_{2/3})O₃−(y)“BaNiO₂”, where [Ni]=(1+2y)/3, [Nb]=2(1-y)/3, and δ=y. For example, the composition may be Ba(Ni_{0.5}Nb_{0.5})O_{3-δ} with y=0.25, or
2. BT solid solutions: (1-x)BaTiO₃−(x)“BNN”=(1-x)BaTiO₃-(x)[(1-y)Ba(Ni_{1/3}Nb_{2/3})O₃−(y)“BaNiO₂”], where [Ni]=x(1+2y)/3, [Nb]=2x(1-y)/3, δ=xy, and [vacancy]=xy/3. Note this is the fraction of vacancies on the oxygen sub-lattice.

With Ni in an expected 2+ state, this barium nickel niobate composition has δ=0.25 (e.g., Ba(Ni_{1/2}Nb_{1/2})O_{2.75}). Based on calculations of a 2×2×3 supercell (x=0.33) and a 4×4×2 supercell (x=0.125), every four holes induced by the substitution of two Ti⁴⁺ by Ni²⁺ ions are compensated by one V_{O}\ddot{} and two Nb⁵⁺ substitutions. For the 2×2×3 supercell, various different configurations of the substitutions (solid solution) are found with different positions of the vacancy and Nb relative to Ni. The most stable location for the vacancies is adjacent to two Ni cations (Ni-V_{O}\ddot{}-Ni) while other arrangements, such as Ni-V_{O}\ddot{}-Nb and Ni-V_{O}\ddot{}-Ti, have higher relative energies, due to charge compensation (Qi, et al. “First-principles study of band gap engineering via oxygen vacancy doping in perovskite ABB′O3 solid solutions,” Phys. Rev. B 84 245206 (2011)). However, when the Ni concentration is fairly low (making Ni—Ni pairs rare), the V_{O}\ddot{} between Ni and Ti becomes the preferred configuration Ni-V_{O}\ddot{}-Ti. Once O vacancies are adjacent to Ni, the relative energy varies only slightly with changes in the Nb arrangement (<21 meV, k_{B}T ≈26 meV at 298 K). Therefore, the overall (1-x)BaTiO₃-(x)Ba(Ni_{1/2}Nb_{1/2})O_{2.75} solid solution is a Boltzmann-weighted average of all possible configurations with O vacancies adjacent to Ni.

The band gap and ferroelectric polarization of oxygen vacancy-containing solid solutions may be calculated for the ferroelectric perovskite composition. In one embodiment, density functional theoretical calculations are performed for the band gap and ferroelectric polarization on oxygen vacancy containing solid solutions in the (1-x)BaTiO₃-(x)Ba(Ni_{1/2}Nb_{1/2})O_{3-δ} system (Table 1). Note that ΔE (eV) is the relative energy with respect to the ground state configuration. The (0.67)BaTiO₃-(0.33)Ba(Ni_{1/2}Nb_{1/2})O_{2.75} (x=0.33) solid solution exhibits calculated polarizations ranging from 0.18 to 0.37 C/m² that are comparable to the BaTiO₃ end-member. Calculations for (0.875)BaTiO₃-(0.125)Ba(Ni_{1/2}Nb_{1/2})O_{2.75} with a 4×4×2 (x=0.125) supercell and a tetragonal structure yield a polarization of 0.19 C/m² for the configuration with the oxygen vacancy between two Ni atoms. This is just slightly smaller than the value obtained (0.21 C/m²) for the tetragonal form of BaTiO₃ with the same pseudopotentials. This suggests that the ferroelectric-to-paraelectric transition temperature of the Ba(Ni_{1/2}Nb_{1/2})O_{2.75} substituted solid solutions will be similar to that of the BaTiO₃ end-member (410 K), with a ferroelectric phase being stable at room temperature.

TABLE 1
The band gaps E_{g} (eV) calculated with different methods
and the polarizations P of various cation arrangements of
the (0.67)BaTiO₃-(0.33)Ba(Ni_{1/2}Nb_{1/2})O_{2.75}

| Configurations | P (C/m²) | E_{g}^{GGA+U} (eV) | E_{g}^{HSE06} (eV) | ΔE (eV) |
|---|---|---|---|---|
| Ni—V_{O}\ddot{ }—Ni | 0.24 | 1.95 | 2.2 | 0 |
| Ni—V_{O}\ddot{ }—Nb | 0.37 | 1.86 | 2.24 | +1.27 |
| Ni—V_{O}\ddot{ }—Ti | 0.18 | 2.35 | 2.16 | +0.75 |

Inspection of the relaxed structures of the BTNNO composition shows that the Ba and Ti off-center displacements in (1-x)BaTiO₃-(x)Ba(Ni_{1/2}Nb_{1/2})O_{2.75} (D_{Ba}=0.06 Å and D_{Ti}=0.13 Å) are slightly reduced compared to those in BaTiO₃ (D_{Ba}=0.1 Å and D_{Ti}=0.15 Å) with the substituent Nb and Ni cations showing smaller displacements of 0.06 Å and 0.01 Å, respectively.

The GGA+U calculations for both of the x=0.33 and x=0.125 compositions (1-x)BaTiO₃-(x)Ba(Ni_{1/2}Nb_{1/2})O_{2.75} give band gaps around 2 eV (Table 1), which are lower than that of BaTiO₃ (2.4 eV). This is confirmed by the HSE06 calculations, where the band gaps for the 2×2×3 supercell (x=0.33) are at least 0.8 eV lower than the band gaps of BaTiO₃ (3.1 eV) (Wang, et al., “Band gap engineering strategy via polarization rotation in perovskite ferroelectrics,” Appl Phys Lett, vol. 104, p. 152903, 2014). Though the actual band gaps may be slightly higher because the HSE06 calculations underestimate the band gaps, the actual band gaps for (1-x)BaTiO₃-(x)Ba(Ni_{1/2}Nb_{1/2})O_{2.75} solid solutions are likely to be ≦2 eV.

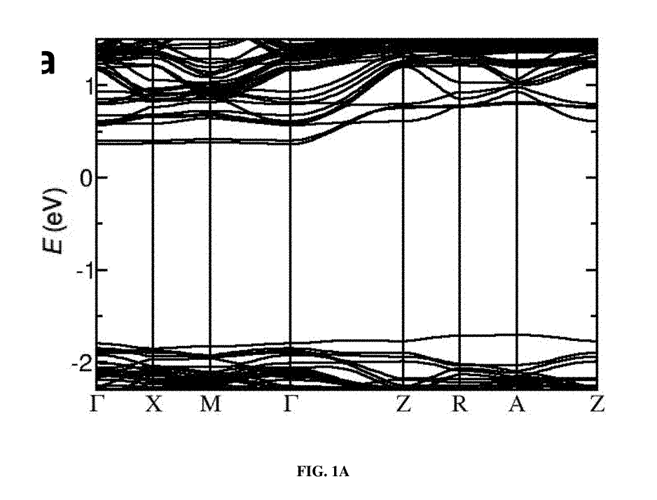

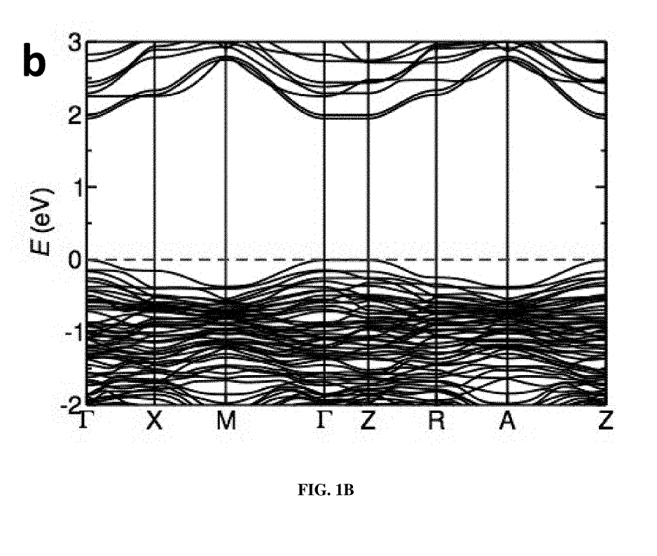

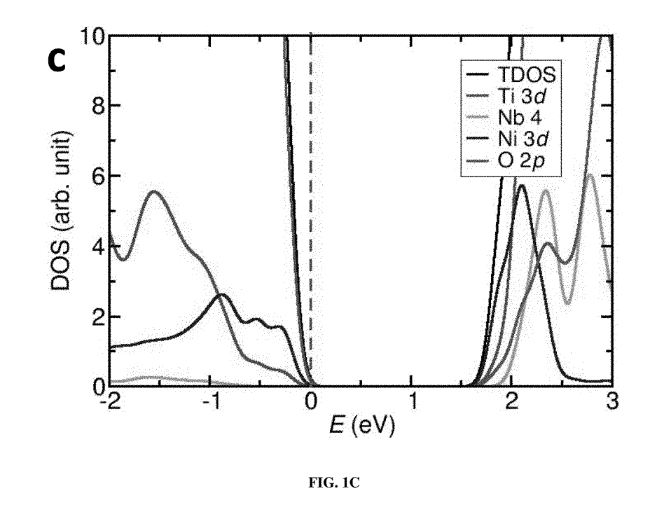

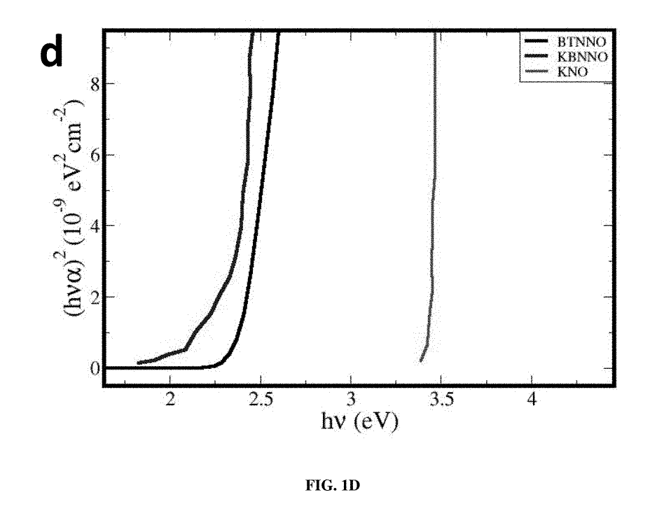

The calculated band structures show that the GGA+U band gap of the x=0.125 solid solution is indirect with a slightly higher direct gap (FIG. 1A) while the gap for x=0.33 is direct (FIG. 1B). In contrast to (K,Ba)(Ni,Nb)O_{3-δ}, the valence band maximum (VBM) in (1-x)BaTiO₃-(x)Ba(Ni_{1/2}Nb_{1/2})O_{2.75} predominantly consists of O 2p orbitals, with Ni 3d orbitals located 0.2 eV below the VBM. The conduction band minimum (CBM) mainly arises from the Ni 3d orbitals hybridizing with Nb 4d, Ti 3d, and O 2p orbitals at higher energy (FIG. 1C). An O 2p to metal d excitation across the gap favors a large transition dipole moment and a large absorption coefficient that are superior to that of KBNNO.

The first-principles calculations indicate that the direct absorption coefficient rises rapidly and reaches 10⁴ cm⁻¹ for photon energies that are 0.2 eV higher than E_{g}. This rise is more rapid than that observed in KBNNO. Comparison of the calculated direct absorption Tauc plots for (1-x)BaTiO₃-(x)Ba(Ni_{1/2}Nb_{1/2})O_{2.75}, KBNNO, and KNbO₃ shows that KNbO₃ follows the predicted direct absorption dependence almost exactly, while the absorption for KBNNO shows a strong deviation from the standard Tauc direct absorption behavior (FIG. 1D). This is due to the different nature of the transition dipole in KBNNO (Ni 3d-Nb 4d) and KNbO₃ (O 2p-Nb 4d). The absorption of (1-x)BaTiO₃-(x)Ba(Ni_{1/2}Nb_{1/2})O_{2.75} is calculated to lie between KBNNO and KNbO₃ due to the mixture of Ni 3d-Nb 4d and O 2p-Nb 4d transitions.

To summarize, first-principles calculations predict that (1-x)BaTiO₃-(x)Ba(Ni_{1/2}Nb_{1/2})O_{2.75} will exhibit several desirable features: significant polarization, a ferroelectric phase at room temperature, band gaps significantly lower (≦2 eV) than those of BaTiO₃, and potentially superior light absorption properties compared to those of KBNNO.

The (1-x)BaTiO₃-(x)Ba(Ni_{1/2}Nb_{1/2})O_{2.75} is representative of the ferroelectric perovskite composition of the present invention. Thus, the ferroelectric perovskite composition would have the desired features of (1-x)BaTiO₃-(x)Ba(Ni_{1/2}Nb_{1/2})O_{2.75}. In some embodiments, the ferroelectric perovskite composition preferably has a band gap in a range of from about 0.8 eV to about 3.1 eV, or from about 1.0 eV to about 2.9 eV, or from about 1.2 eV to about 2.7 eV, or from about 1.4 eV to about 2.5 eV, or from about 1.4 eV to about 2.3 eV, or from about 1.6 eV to about 2.3 eV, or from about 1.6 eV to about 2.1 eV, or from about 1.8 eV to about 2.1 eV.

In some embodiments, the ferroelectric perovskite composition preferably exhibits a measurable absorption of greater than about 104 cm⁻¹, or greater than about 106 cm⁻¹, or greater than about 108 cm⁻¹, or greater than about 110 cm⁻¹, or greater than about 112 cm⁻¹, or greater than about 114 cm⁻¹, or greater than about 116 cm⁻¹, or greater than about 118 cm⁻¹, or greater than about 120 cm⁻¹, or greater than about 122 cm⁻¹, or greater than about 124 cm⁻¹, or greater than about 126 cm⁻¹, throughout the entire visible wavelength spectrum.

In some embodiments, the ferroelectric perovskite composition preferably exhibits a ferroelectric switching in a temperature up to about 400 K, or up to about 380 K, or up to about 350 K, or up to about 330 K, or up to about 300 K, or up to about 298 K, or up to about 296 K, or up to about 294 K, or up to about 292 K, or up to about 290 K, or up to about 288 K, or up to about 286 K, or up to about 284 K, or up to about 282 K, or up to about 280 K, or up to about 278 K, or up to about 276 K, or up to about 275 K.

In some embodiments, the ferroelectric perovskite composition preferably exhibits a photovoltaic effect with a measurable, non-zero open-circuit voltage and a measurable, non-zero short-circuit current. In some other embodiments, the ferroelectric perovskite composition preferably exhibits a ferroelectric photovoltaic effect. The ferroelectric photovoltaic effect is preferably represented by reversing the polarity of current of the photovoltaic effect after electrical poling in the opposite film plane-normal direction.

In some embodiments, the ferroelectric perovskite composition preferably is in a form selected from ceramic, crystalline, and a film.

In some embodiments, bulk ferroelectric perovskite composition such as a BaTiO₃-Ba(Ni_{0.5}Nb_{0.5})O_{3-δ} composition may be formed by introduction of Ni²⁺-V_{O}\ddot{} pairs by substituting Ba(Ni_{1/2}Nb_{1/2})O_{2.75} into BaTiO₃. In one embodiment, the composition is Ba(Ni_{1/2}Nb_{1/2})O_{2.75} with y=0.25 within the (1-y)Ba(Ni_{1/3}Nb_{2/3})O₃-(y) “BaNiO₂” (BNN) pseudo-binary system, where the nominal V_{O}\ddot{} content y can be controlled by changing the ratio of Ni:Nb=(1+2y)/2(1-y) of the BNN.

The low band-gap ferroelectric composition may be made from bulk BaTiO₃ materials by including a controlled range of coupled Ni²⁺:Nb⁵⁺:V_{O}\ddot{} substitutions. To evaluate the effect of the Ni:Nb ratio on the structure and optical response of BaTiO₃, a series of co-doped Ni/Nb (1-x) BaTiO₃-(x)BNN compositions with a fixed concentration of Ni have been synthesized (Table 2) by standard solid-state synthesis methods.

TABLE 2
Compositions of BNN-substituted BaTiO₃
(1 − x)BaTiO₃—(x)[(1 − y)Ba(Ni_{1/3}Nb_{2/3})O₃—(y)“BaNiO₂”]

| | | | | % Ni | | Oxygen |
|---|---|---|---|---|---|---|
| | | | | on B- | [Ni/Ni + | vacancy |
| Composition | Formula | x | Y | site | Nb]% | conc.* |
| A | Ba(Ti_{0.85}Ni_{0.05}Nb_{0.1})O₃ | 0.15 | 0 | 5% | 33% | 0% |
| B | Ba(Ti_{0.857}Ni_{0.05}Nb_{0.093})O_{2.99643} | 0.143 | 0.025 | 5% | 35% | 0.12% |
| C | Ba(Ti_{0.8667}Ni_{0.05}Nb_{0.0833})O_{2.99167} | 0.1333 | 0.0625 | 5% | 37.5% | 0.28% |
| D | Ba(Ti_{0.875}Ni_{0.05}Nb_{0.075})O_{2.9875} | 0.125 | 0.1 | 5% | 40% | 0.42% |
| E | Ba(Ti_{0.9}Ni_{0.05}Nb_{0.05})O_{2.975} | 0.1 | 0.25 | 5% | 50% | 0.83% |
| F | Ba(Ti_{0.95}Ni_{0.05}Nb_{0.05})O_{2.95} | 0.05 | 1 | 5% | 100% | 1.67% |

*The oxygen vacancy concentration of each composition is calculated based on that Ni holds 2+ valence state in the solid solution.

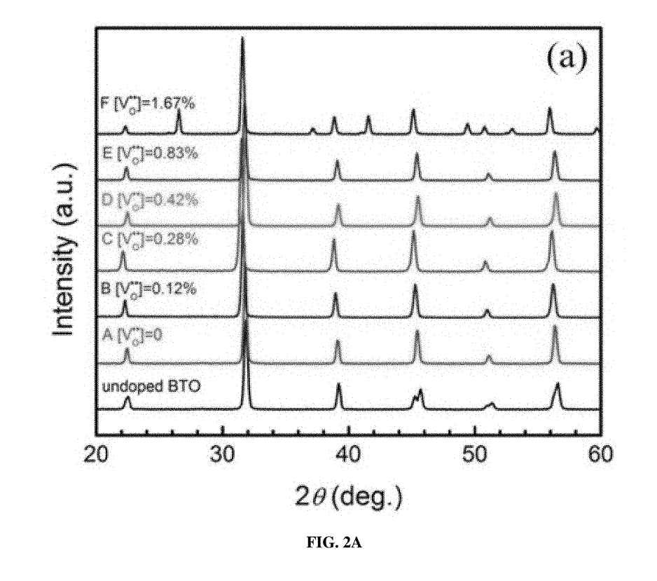

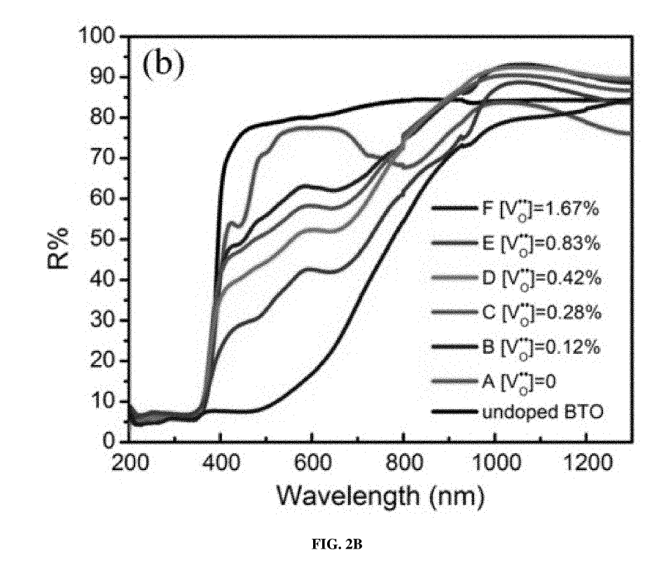

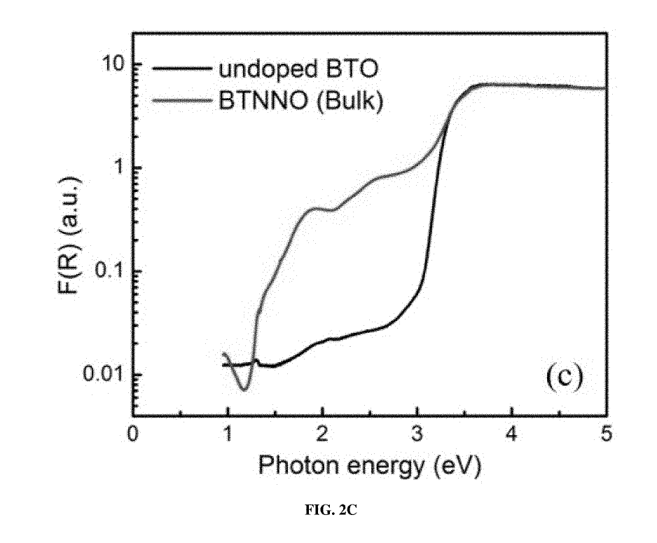

The nominal V_{O}\ddot{} concentration of each composition in Table 2 is calculated based on the assumption that Ni retains a 2+ valence state in the solid solution. X-ray diffraction patterns (XRD) collected from compositions A-F containing 5% Ni on the B-site with 0≦y≦1 are shown in FIG. 2A together with that of undoped BaTiO₃. These compositions can all be indexed in terms of a cubic close packed (ccp) perovskite structure with an {. . . ABC . . . } stacking sequence of the BaO₃ layers along the <111> pseudocubic direction. Composition F, which is the pure Ni-doped composition BaTi_{0.95}Ni_{0.05}O_{2.95}, has a pattern characteristic of the hexagonal polymorph of BaTiO₃ with an {. . . ABCBAC . . . } stacking sequence of the BaO₃ layers along <111>ₚ. The stabilization of the hexagonal polymorph of BaTiO₃ with ≦5% substitution of Ni acceptors and ≦1.67% of the accompanying V_{O}\ddot{} has been reported previously (Fukunaga, et al., “Structural and dielectric properties of nickel-doped and lanthanum-chromium-doped barium titanate ceramics,” J. Jour. Appl. Phys., 41, 2002; Keith, et al., “Synthesis and characterization of 6H—BaTiO₃ ceramics,” J. European Ceramic Society, vol. 24, pp. 1721-1724, 2004). These results indicate that the ccp polymorph of BaTiO₃, which supports ferroelectric correlations, can accommodate at least 0.83% V_{O}\ddot{} by co-doping with Ni and Nb through the use of a BNN type end-member.

The ultraviolet-visible (UV-Vis) spectra of BNN-substituted BaTiO₃, as shown in FIG. 2B, reveal a systematic increase in the absorption between 400 nm and 1000 nm as the concentration of oxygen vacancies, controlled by the ratio of Ni:Nb, increases. In particular, compositions E and F show a strong absorption due to high concentrations of Ni²⁺-V_{O}\ddot{} pairs. This demonstrates that this is an effective way of tuning visible light absorption via chemical substitutions and oxygen vacancy engineering. Although composition F shows the highest absorption, it is not ferroelectric at room temperature due to its hexagonal structure.

Composition E, with formula (0.9)(BaTiO₃)-(0.1)(BaNi_{0.5}Nb_{0.5}O_{2.75}), which retained the cubic stacking sequence of pure BaTiO₃, is further characterized. Throughout this application, composition E (0.9)(BaTiO₃)-(0.1)(BaNi_{0.5}Nb_{0.5}O_{2.75}) is referred to as BTNNO. The UV-Visible spectra of BTNNO after a Kubelka-Munk transformation are shown in FIG. 2C. Beginning at approximately 1.3 eV, the optical absorption in the visible range increases dramatically compared to that of undoped BaTiO₃. BTNNO shows an absorption edge located close to 3.2 eV, similar to that of the end-member BaTiO₃, and significant absorption down to almost 1 eV.

In some embodiments, the ferroelectric perovskite composition is in the form of a film, which is preferably produced by a method selected from physical vapor deposition, chemical vapor deposition, metal organic chemical vapor phase deposition, atomic layer deposition, and a sol-gel process.

In some embodiments, the ferroelectric perovskite film preferably has a thickness in a range of from about 1 nm to about 10,000 nm, or from about 5 nm to about 9,000 nm, or from about 10 nm to about 8,000 nm, or from about 15 nm to about 7,000 nm, or from about 20 nm to about 6,000 nm, or from about 25 nm to about 5,000 nm, or from about 30 nm to about 4,000 nm, or from about 35 nm to about 3,000 nm, or from about 40 nm to about 2,000 nm, or from about 45 nm to about 1,000 nm, or from about 50 nm to about 900 nm, or from about 55 nm to about 850 nm, or from about 60 nm to about 800 nm, or from about 65 nm to about 750 nm, or from about 70 nm to about 700 nm, or from about 75 nm to about 650 nm, or from about 80 nm to about 600 nm, or from about 85 nm to about 550 nm, or from about 90 nm to about 500 nm, or from about 95 nm to about 450 nm, or from about 100 nm to about 400 nm.

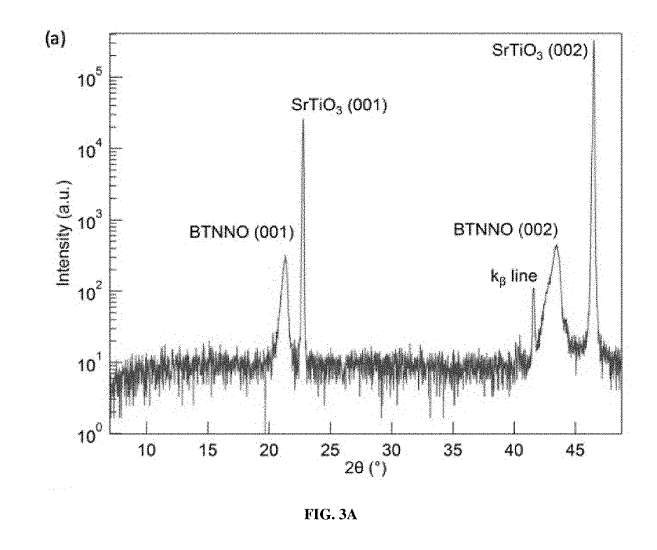

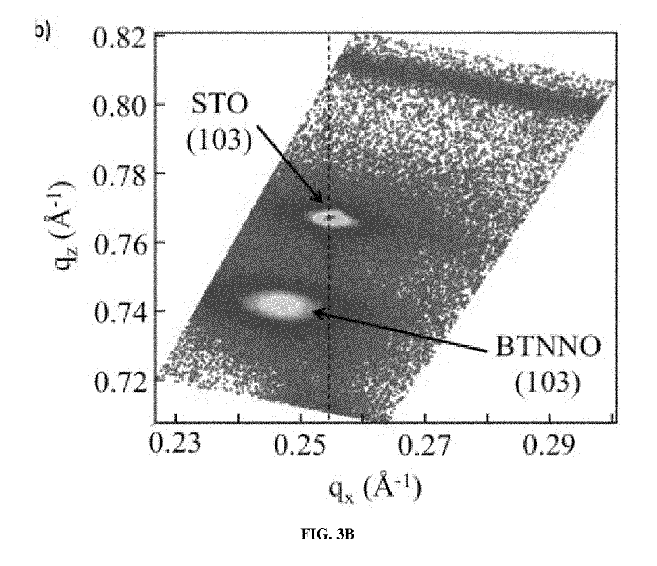

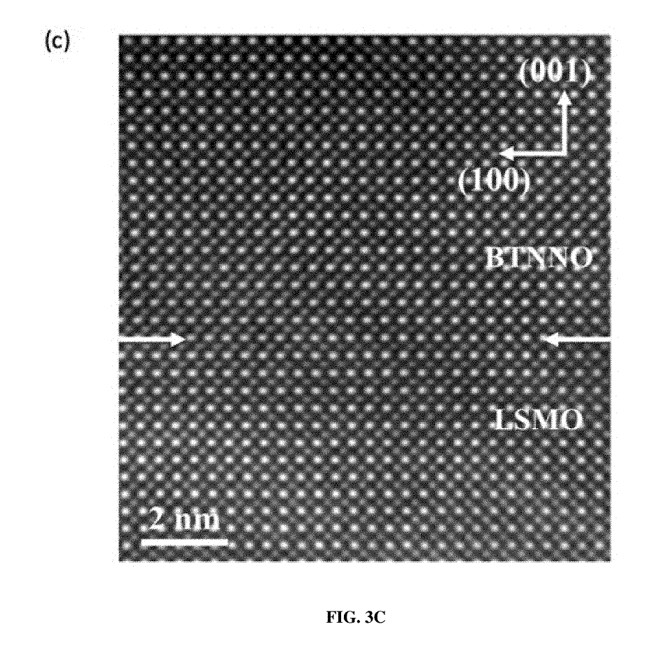

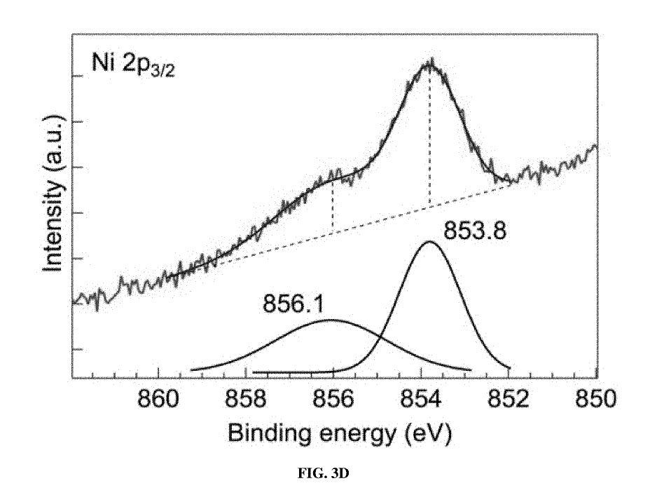

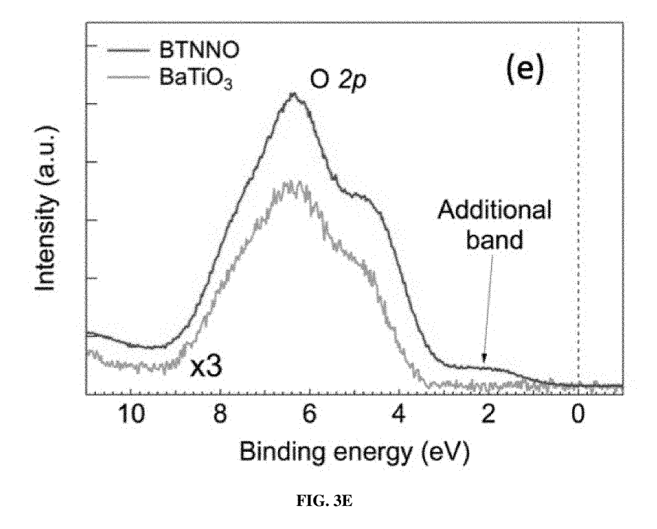

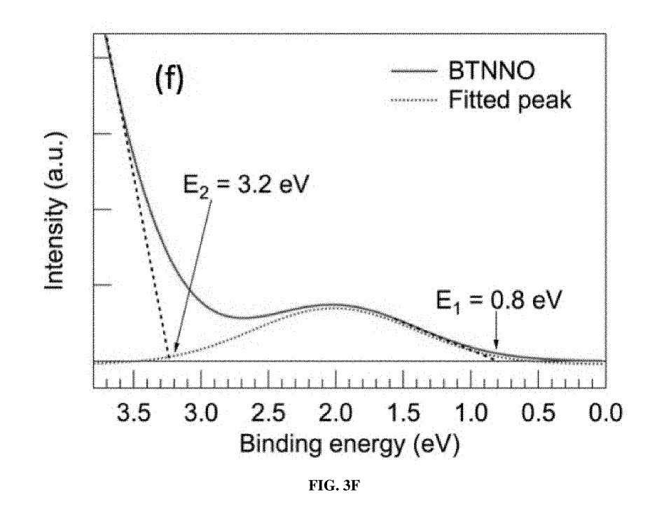

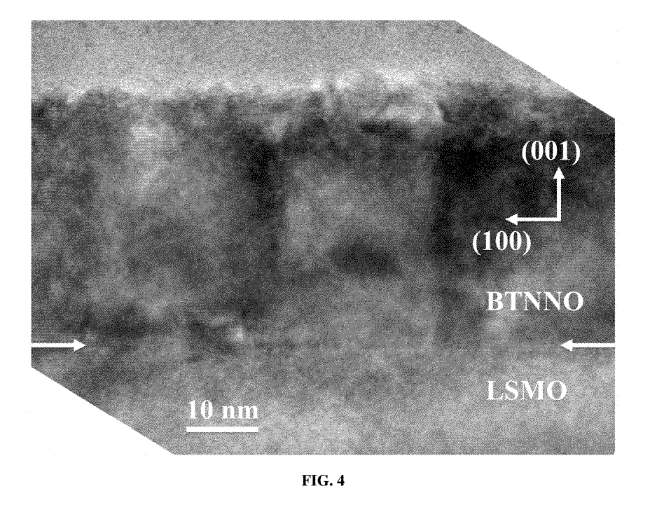

In some embodiments, the film is an epitaxial BTNNO thin film, which is a (001)-oriented epitaxial film of BTNNO grown by pulsed-laser deposition (PLD) on (001) a SrTiO₃ substrate. The XRD shows that the BTNNO films exhibit a high-quality epitaxy on a (001) SrTiO₃ substrate (FIG. 3A). Reciprocal space mapping (RSM) measurements reveal that the films (≈100 nm thick) appear to be partially relaxed (FIG. 3B). High-resolution transmission electron microscopy (TEM) images show a good crystalline quality of the films and a coherent interface between an electrode layer (La_{0.7}Sr_{0.3}MnO₃) and BTNNO (FIG. 3C), as well as the presence of cubic structural domains (FIG. 4).

XPS spectra of the valence band structure of the BTNNO film revealed additional band states (as compared to pure BaTiO₃, Chynoweth, “Surface space-charge layers in barium titanate,” Phys. Rev., 102, 1956) with a peak at about 2 eV (FIGS. 3D-3E) originating from the Ni 3d states and their hybridization with O 2p, as shown in FIG. 1C. Notably, the peak represents an additional density of states that can effectively reduce the optical band gap of the BTNNO material. An expanded view of the region near the Fermi level is shown in FIG. 3F. Linear approximation of the two slopes, one from the assigned Ni 3d peak and the other from the O 2p peak, yields two bands at E₁=0.8 eV and E₂=3.2 eV. The value of E₂ is very close to the valence band minimum of pure BaTiO₃ (3.3 eV, as determined by XPS/UPS, Hudson, et al., “Photoelectron spectroscopic study of the valence and core-level electronic structure of BaTiO3,” Phys. Rev. B 47, 1993), suggesting a negligible band offset at the interface between the BTNNO film and Nb:SrTiO₃ substrate. The energy of the band states related to the Ni 3d-O 2p hybridization is much smaller, its value (0.8 eV; λ≈1550 nm) lying reasonably close to the absorption observed in the UV-Vis spectra of the bulk samples presented in FIGS. 2A-2C. A small difference in the absorption edge in the UV-Vis and XPS spectra may be due to the different probing depths and the fact that the epitaxial BTNNO film could have various degrees of local strain.

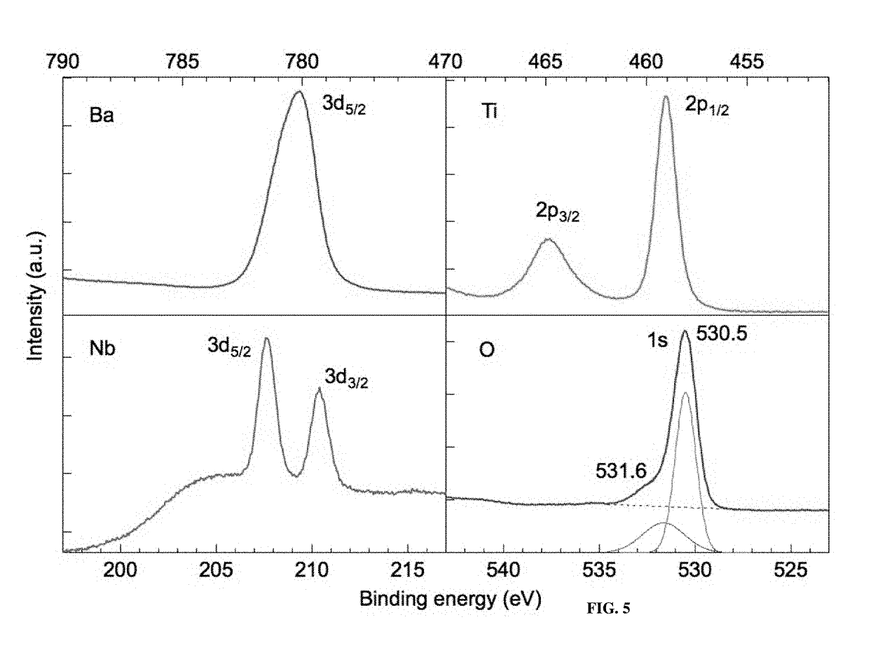

The oxidation states of the cations in BTNNO film play an important role in the band engineering and optical absorption. Thus, a thorough XPS analysis may be used to characterize the constituent elements of the BTNNO film. The XPS spectra of the BTNNO film on a conducting (001) Nb:SrTiO₃ substrate is shown in FIG. 5. The oxygen is peak has a higher energy (531.6 eV), which is attributed to surface contaminants. The ion sputtering conditions is controlled to ensure no amorphization occurs on the surface of the film, which could leave some groups such as —CO₃ on the surface.

The Ba and Nb cations that are not expected to play a role in the formation of oxygen vacancies remain in their predicted oxidation states of 2+ and 5+, respectively (FIG. 5). The Ti 2p_{3/2} peak also does not reveal any deviation from a Ti⁴⁺ state (FIG. 5). However, the XPS spectrum reveals two peaks for Ni: a main peak at 853.8 eV and a satellite peak at 856.1 eV. The binding energy of the main peak correlates well with the expected position for a Ni²⁺ oxidation state (Biesinger, et al., “X-ray photoelectron spectroscopic chemical state quantification of mixed nickel metal, oxide, and hydroxide systems,” Surface and Interface Analysis, vol. 41, pp. 324-332, 2009; Gottschall, et al., “Electronic state of nickel in barium nickel oxide, BaNiO₃,” Inorganic Chemistry, vol. 37, pp. 1513-1518, 1998). The satellite peak, having a higher binding energy, could indicate the presence of Ni³⁺ in the film. Integration of the two peaks yielded a 3:1 molar ratio of the two Ni species in the BTNNO film.

It is expected that, at high-temperature conditions such as are required to form bulk ceramic samples, Ni would primarily be present in the 2+ valence state. While the XPS results confirm this is the major valence state for Ni in the bulk BaNi_{0.5}Nb_{0.5}O_{2.75} substituted BaTiO₃, some degree of oxidation to Ni³⁺ with an associated partial filling of the oxygen vacancies is possible under the lower-temperature conditions used in the deposition of the BTNNO films.

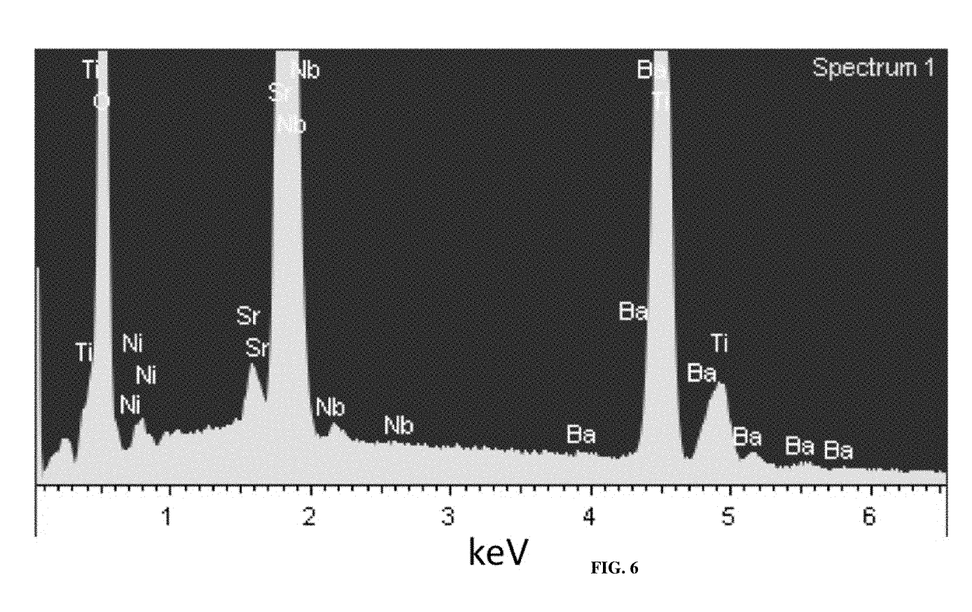

The chemical composition of the BTNNO films was further validated using energy-dispersive X-ray spectroscopy (EDX) and XPS analysis. A typical EDX spectrum of the film is shown in FIG. 6. The peaks from the low-quantity elements such as Ni and Ba can be distinguished. The chemical composition derived from the EDX and XPS analyses is shown in Table 3. In the EDX column, the Ba:Nb:Ni ratio is about 1:0.09:0.07, which is essentially identical to the initial bulk composition (considering the possible error in the EDX spectrometer, which is typically within 5% for the well-shaped peak). XPS analysis shows a decreased amount of Ni, which may be due to the fact that XPS probes only the surface or that the spectrum for Ni was not collected for a long enough time. Most importantly, the ratio of Ba:(Ti+Ni+Nb) is about 1, similar to that in the initial ceramic composition.

TABLE 3
Chemical composition of the BTNNO/Nb:SrTiO₃ film

| | |
|---|---|
| EDX | XPS |

| Element | Atomic % | Element | Binding Energy | Atomic % |
|---|---|---|---|---|
| O K | 68.06 | O 1s | 530.5 | 64 |
| Ti K | 15.06 | Ti 2p_{3/2} | 459.05 | 16.8 |
| Ni K | 0.18 | Ni 2p_{3/2} | 853.75 | 0.3 |
| Ba L | 2.46 | Ba 3d_{5/2} | 780.1 | 17.6 |
| Nb L | 0.23 | Nb 3d | 207.6 | 1.3 |
| Sr L | 15.02 | | | |

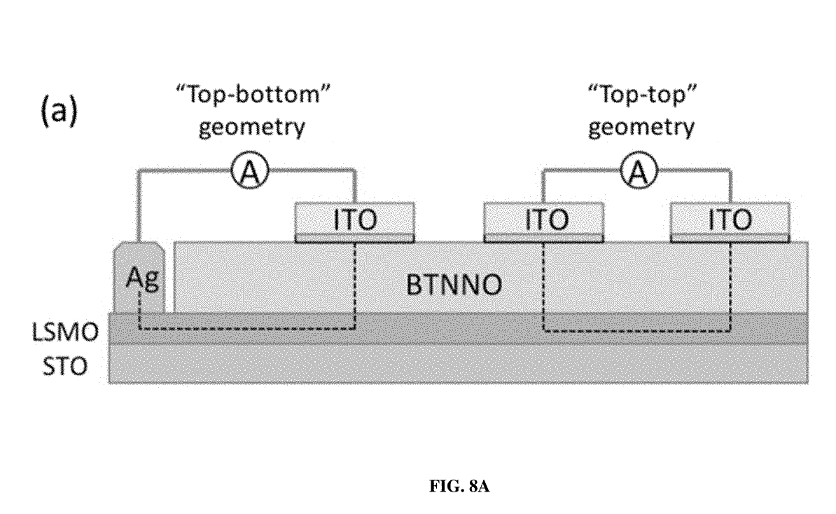

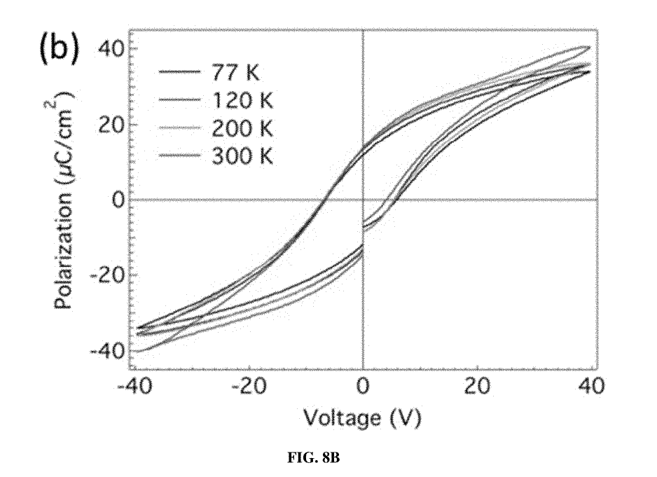

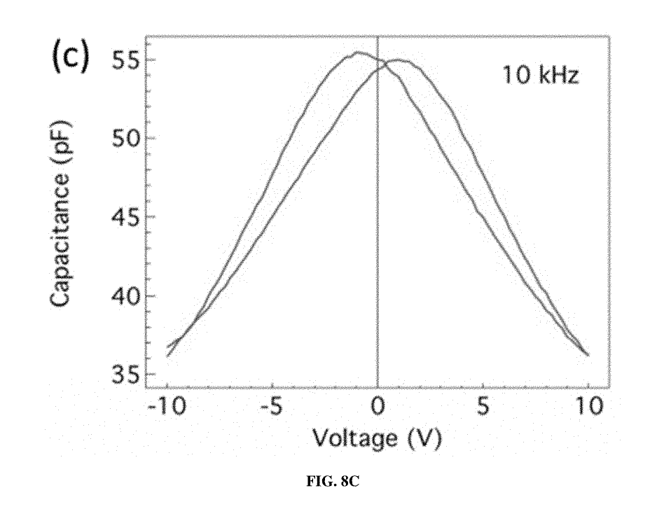

BTNNO film also exhibits ferroelectric switching and a switchable bulk photovoltaic effect. To make a photovoltaic panel, an La_{0.67}Sr_{0.33}MnO₃ bottom-film electrode is deposited on the (001) SrTiO₃ substrate of the BTNNO film, followed by deposition of a semi-transparent top electrode 85×85 μm² consisting of Au and indium tin oxide layers on the BTNNO film with a shadow mask. The two-electrode configuration may be used in: (a) a conventional metal-ferroelectric-metal “top-bottom” geometry, where the bias is applied between the top and the bottom contacts; and (b) a “top-top” geometry, where the film polarizations underneath two top electrodes are poled (with respect to the bottom electrode) in film plane-normal, anti-parallel directions (FIG. 8A).

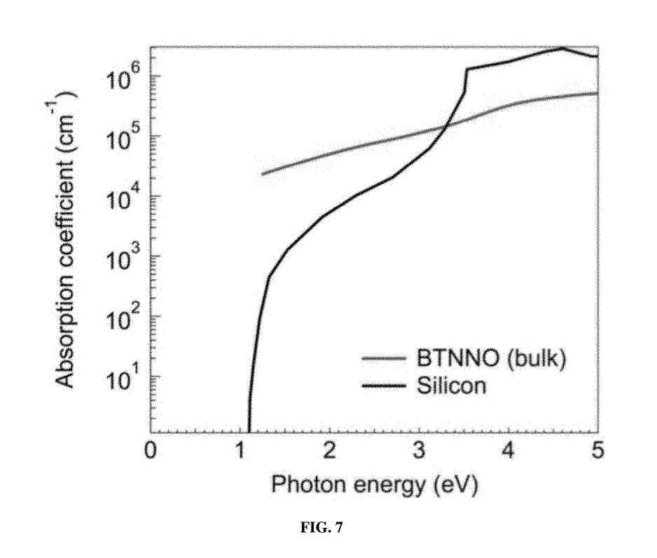

The energy absorbed by the photovoltaic panel, or activation energy, is called energy E1. The energy E1 represents the valence band minimum, presumably caused by the defect states via BNNO doping. Spectroscopic ellipsometry of the bulk BTNNO ceramic pellet (black color) is shown in FIG. 7, with a Si-based material as a comparison. The BTNNO has a significant absorption extending down to almost 1 eV.

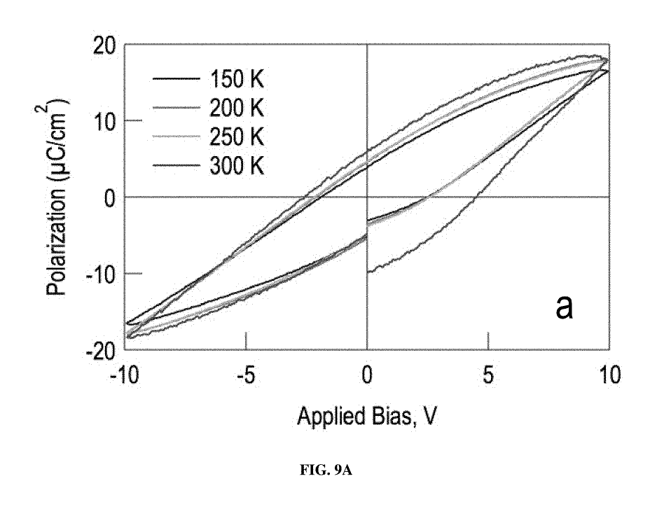

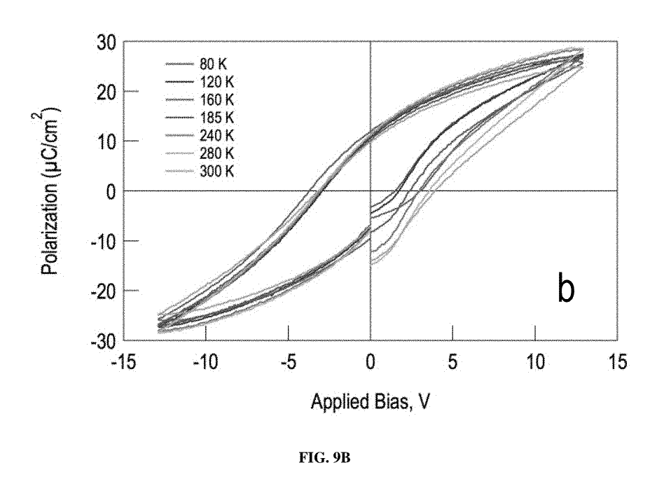

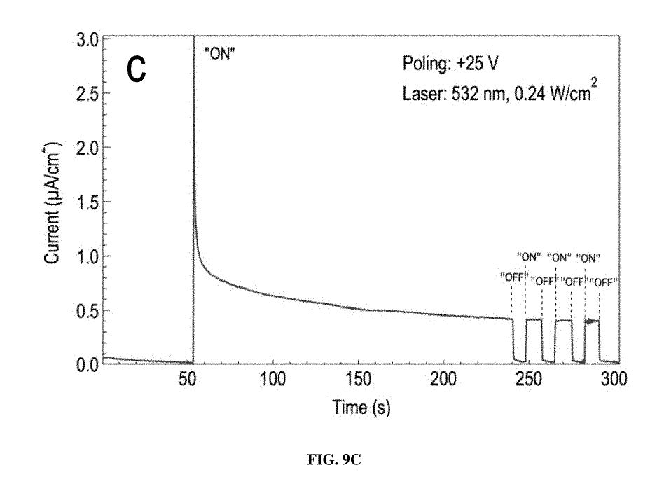

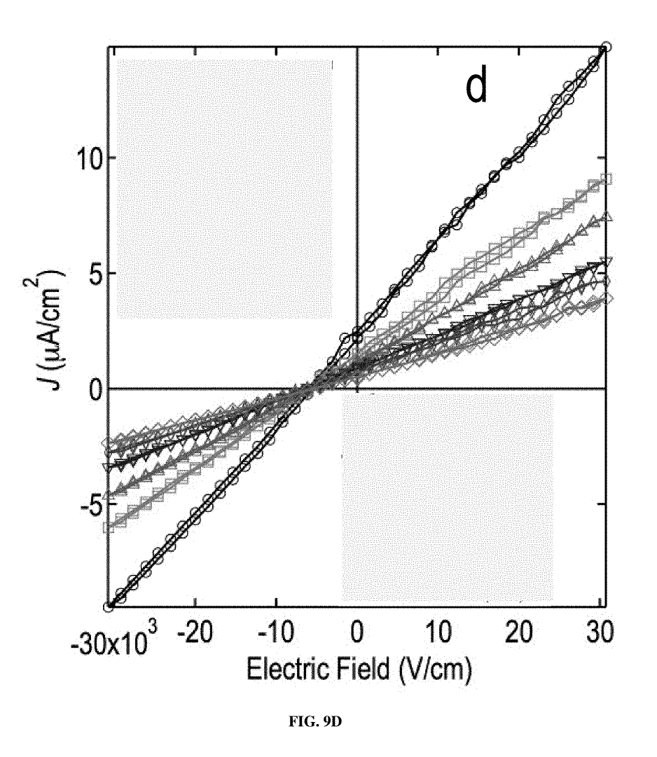

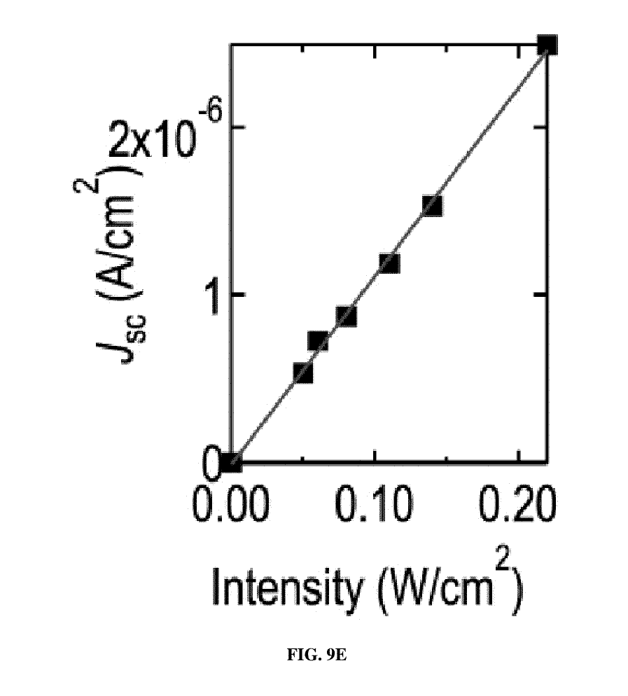

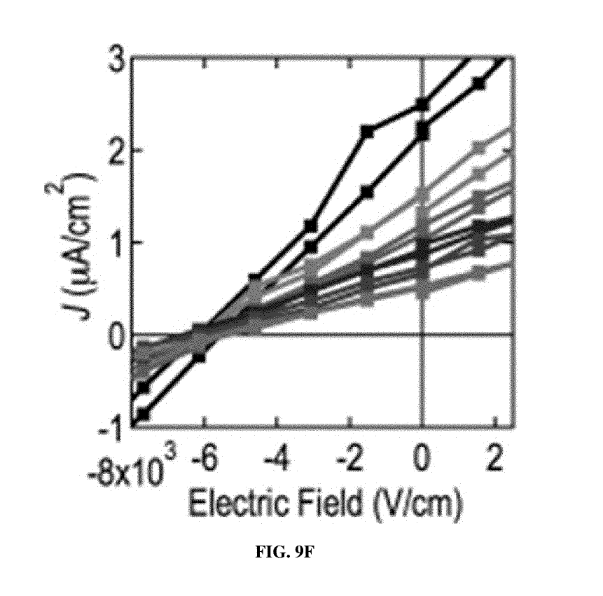

Photocurrent-voltage traces are collected using the two top electrodes while electrically floating the bottom electrode. Since the spacing between the two top electrodes is more than two orders of magnitude greater than the film thickness, photocurrent flowed predominantly in the film plane direction and along a single polarization direction (FIG. 8A), whereby the effects of electrode asymmetry are removed. Ferroelectric testing has been performed for the films with different thicknesses (≈80 and 130 nm) at various switching rates in the temperature range of 80-300 K. The capacitance-versus-voltage measurements show a typical “butterfly” loop, which also confirms polarization switching in the BTNNO films (FIGS. 8B-8C). Robust ferroelectric switching is observed in the films at each temperature (FIGS. 9A-9B).

The effect of ferroelectric poling on the short-circuit photocurrent is investigated in a 130 nm thick BTNNO film under illumination with light at wavelengths of 476 nm and 532 nm. After the film is pre-poled (+25 V pulse, 100 s), the photovoltaic current exhibits an initial jump (FIG. 9C), which is due to screening and pyroelectric contributions (Chen, “Optically induced change of refractive indices in LiNbO3 and LiTaO3,” J. Appl. Phys. vol. 40, pp. 3389-3396, 1969). Periodic “on/off” switching of the illumination results in the abrupt drop and reappearance of the photocurrent without any significant current relaxation.

Current-voltage traces were collected for the BTNNO films after the current reached steady state. Typical responses under 405 nm wavelength illumination at different intensities revealed short-circuit photovoltaic currents of up to about 2.5 μA/cm² for intensities up to about 200 mW/cm² (FIG. 9D). These results are similar to those observed in BaTiO₃ films under illumination with a slightly shorter wavelength (360 nm) and a comparable intensity (Zenkevich, et al., “Giant bulk photovoltaic effect in thin ferroelectric BaTiO3 films,” Phys Rev B, 90, 161409, 2014). The consistent value of zero-current photo-voltage (Voc ≈6 kV/cm, under 405 nm wavelength illumination) at different illumination intensities and the linear variation in short-circuit current with intensity confirm the bulk photovoltaic origin of the response (FIGS. 9E-F).

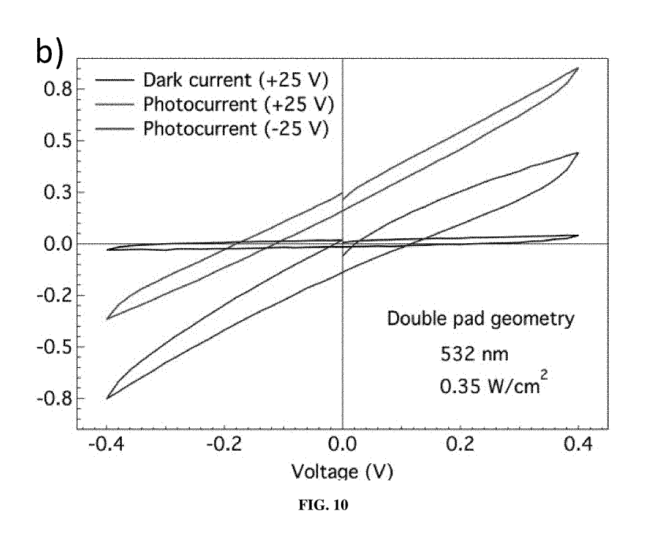

FIG. 10 shows I-V characteristics of the BTNNO film in a double-pad geometry under illumination at a wavelength of 532 nm, where a clear switchable photovoltaic effect is present. Typical open-circuit photo-voltages reached about 0.2 V for about 260 nm of the total thickness of the BTNNO films, which corresponds to the normalized value of about 8 kV/cm. This value is much larger than the V_{OC} of a BiFeO₃ (band gap is 2.2 eV) single crystal (˜60 μm thick) illuminated using a similar wavelength, but is very close to the values of 0.2-0.3 V reported for BiFeO₃ thin films with thicknesses of 150-400 nm (Katiyar, et al., “Photovoltaic effect in a wide-area semiconductor ferroelectric device,” Applied Physics Letters, vol. 99: p. 092906, 2011; Ji, et al., “Bulk Photovoltaic Effect at Visible Wavelength in Epitaxial Ferroelectric BiFeO3 Thin Films,” Advanced Materials, vol. 22, p. 1763-1766, 2010; Yamada, et al., “Measurement of transient photoabsorption and photocurrent of BiFeO3 thin films: Evidence for long-lived trapped photocarriers,” Physical Review B, vol. 89, p. 035133, 2014).

Hysteresis in photocurrent-voltage response is observed in the BTNNO films when voltage scanning rates are relatively rapid, as demonstrated in the data shown above. Such pseudocapacitance effects can be suppressed by scanning more slowly.

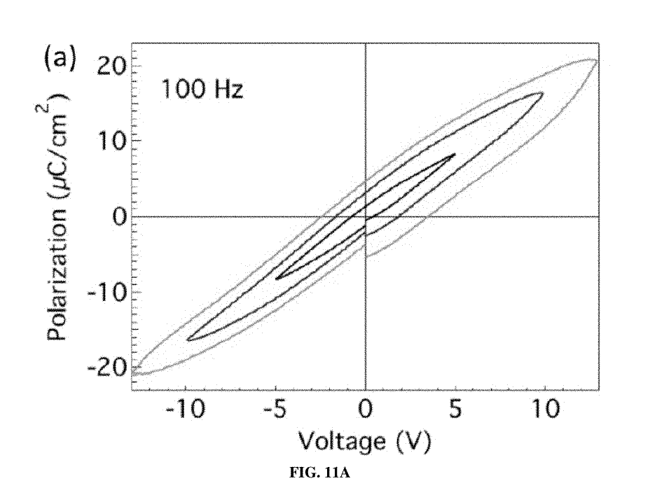

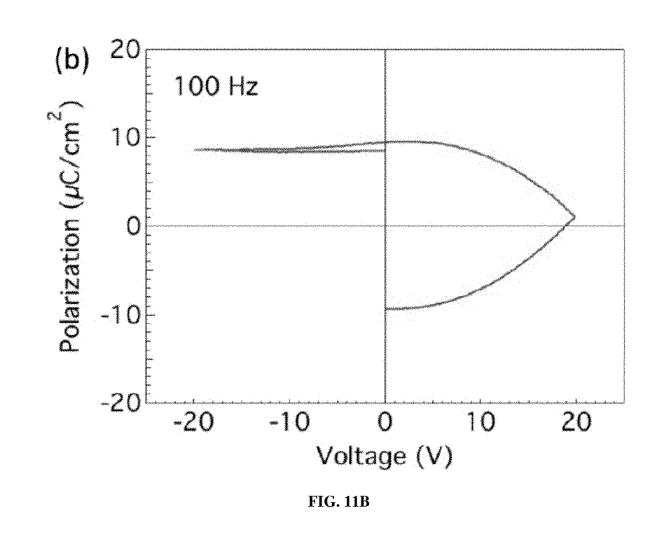

Further study was conducted to compare the ferroelectric characteristics of BaTiO₃ films to BTNNO films. A few BaTiO₃ thin films have been grown by PLD for this study. The shape of the ferroelectric loops of BTNNO films depends on the PLD conditions (FIGS. 11A-11B). The ferroelectric switching in the BTNNO films grown on Nb:SrTiO₃ (FIG. 11A) exhibits less leakage than in the films grown after 7-8 months under identical conditions (FIG. 11B). This may be due to target deterioration over time or deviation of the PLD parameters with time. The latter could cast a formation of under-oxidized film, where Ti³⁺/Ti²⁺ cations with oxygen vacancies are known to induce heavy leakage. Post-deposition annealing (or cooling-down in oxygen) is found to be important for the insulating behavior of the films. As shown in FIG. 11B, the BTNNO film is not as excessively leaky and can be poled under sufficient bias applied for a long time (for example, BiFeO₃ films with larger leakage are poled using a 3 msec pulse with voltages above the coercive field).

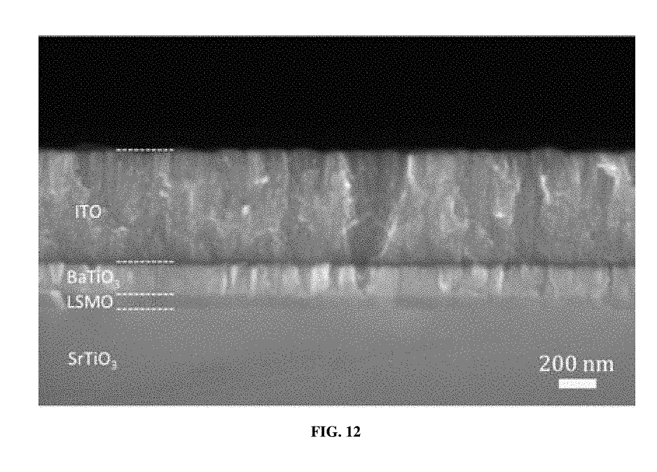

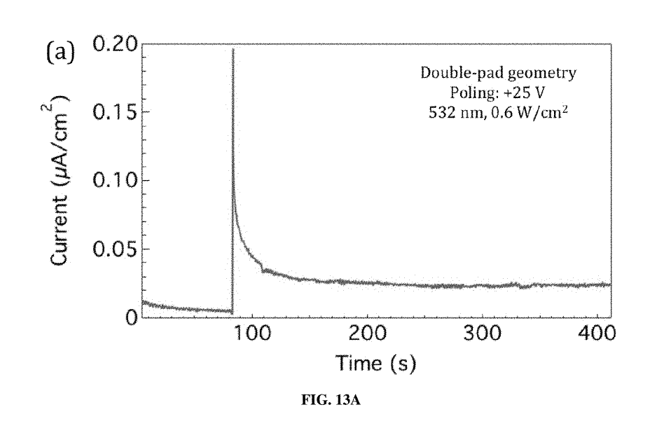

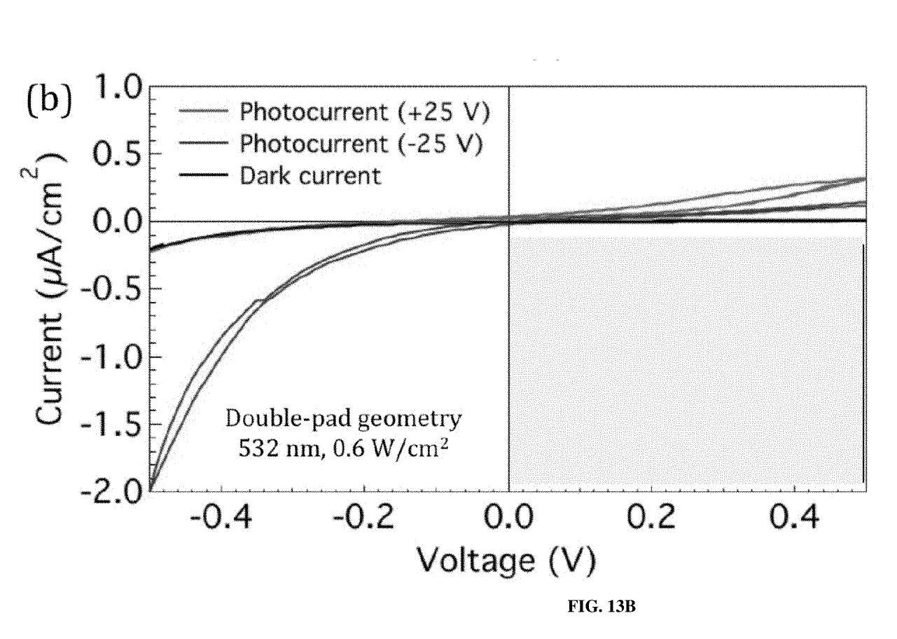

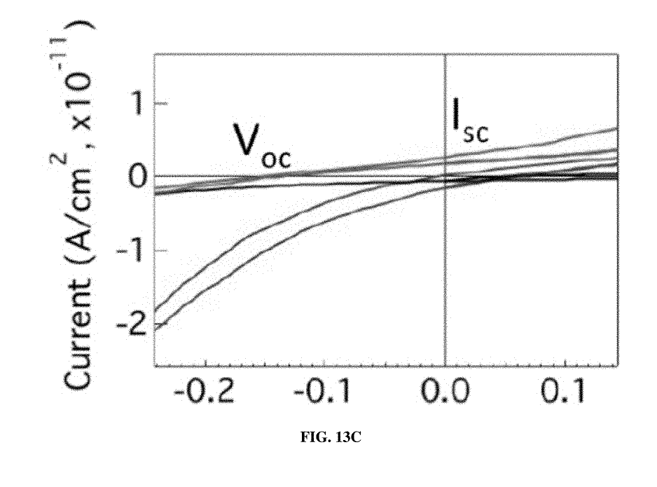

FIG. 12 shows a poled BaTiO₃ film grown on LSMO/SrTiO₃(001) under the same laser illumination as the BTNNO films. The BaTiO₃ film exhibits a noticeably smaller photovoltaic current of ˜0.02 μA/cm², while V_{oc, negative} is −0.15 V and V_{oc, positive} is 0.02 V (average photo-voltage is then <about 0.07 V) (FIGS. 13A-13C). Although typical BaTiO₃ single crystals are visibly transparent, thin films of BaTiO₃ can still absorb light in the visible range of the spectrum due to the presence of oxygen vacancies. For example, BaTiO₃ single crystals showed optical absorption peaks at 460 nm and 510 nm when the sample was anodically reduced, the origin of which can be related to the appearance of Ti²⁺ and/or the contribution from native impurity ions such as Ni. On the other hand, BaTiO₃ thin films are very susceptible to oxygen vacancies and their formation can cause an increase in visible light absorption.

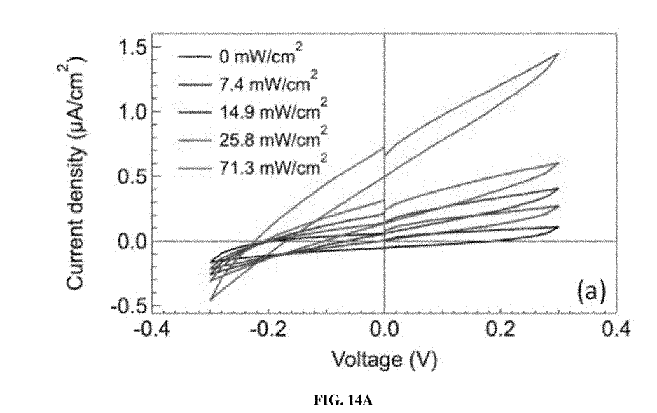

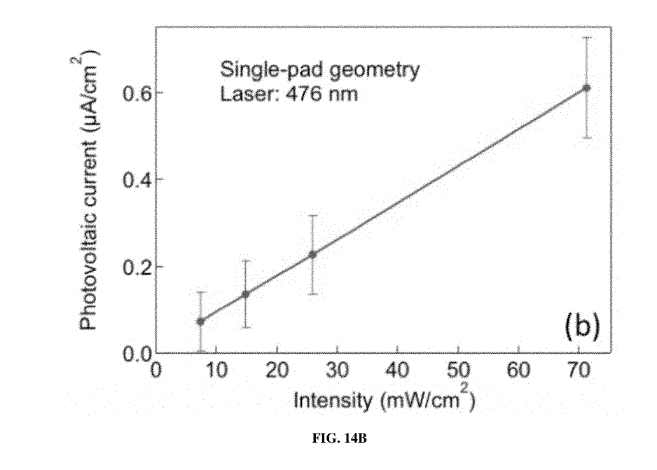

In the symmetric “top-top” geometry, which provides an effective BTNNO film thickness that is the geometric thickness, symmetric switching of the photovoltaic response is observed, producing photovoltages of about 0.1 V (photovoltaic field of about 3.8 kV/cm) under longer-wavelength (532 nm, 350 mW/cm²) illumination (FIG. 14). The bulk photovoltaic effect is identified as a phenomenon linearly dependent on the light intensity. Such a linear dependence is observed for the BTNNO thin films (FIG. 14), further indicating that the photovoltaic effect originates from the ferroelectric polarization of the films.

An important peculiarity of the BTNNO photovoltaic materials is a hysteretic behavior of the I-V characteristics, for both the film form and the bulk material form. This behavior has not been reported for BaTiO₃ or BiFeO₃, which may have a strong capacitance contribution to the current generated in the materials. Since BTNNO films contain some amount of oxygen vacancies, it is possible that their migration upon sweeping the voltage makes a significant contribution to the capacitive behavior. The role of the oxygen-defect-mediated switchable p-n junction that appeared in the BTNNO film is not clear.

A persistent challenge in semiconducting ferroelectrics such as KNbO₃-based solid solutions is unacceptably large conductivity in dark, limiting observability of ferroelectric hysteresis in KBNNO to temperatures well below room temperature. The present invention provides new photovoltaic materials with modifications of the archetypal ferroelectric BaTiO₃ by incorporating nickel, niobium, and/or oxygen vacancies, which leads to light absorption throughout the visible spectrum, without loss of ferroelectric polarization at room temperature. Epitaxial BaNi_{0.5}Nb_{0.5}O_{2.75}-doped BaTiO₃ films of the present invention have the advantages of combining broad-spectrum absorption down to 1 eV, the ferroelectric properties of the parent BaTiO₃ at room temperature, and photovoltaic response to visible wavelength illumination. These films are promising for practical, visible-wavelength-absorbing ferroelectric oxide photovoltaics and other optoelectronic applications.

The epitaxial thin film growth of the new photovoltaic material can be performed similarly to the growth the parent BaTiO₃, allowing for its potential use as an epitaxial semiconductor ferroelectric layer in photovoltaic heterostructures and superlattices, or as a substitute for the ferroelectric BaTiO₃ layer in optical devices.

By introducing Ni²⁺—O vacancy pairs in the ferroelectric BaTiO₃, a significant increase in the optical absorption is achieved. Thin films of the ferroelectric photovoltaic material are developed despite significant challenges for controlling the stoichiometry. The chemical doping approach for the reduction of the band gap is also used to develop the new ferroelectric thin films based on BaTiO₃. These materials showed a switchable photovoltaic effect under visible light illumination along with the retention of the ferroelectric properties above room temperature.

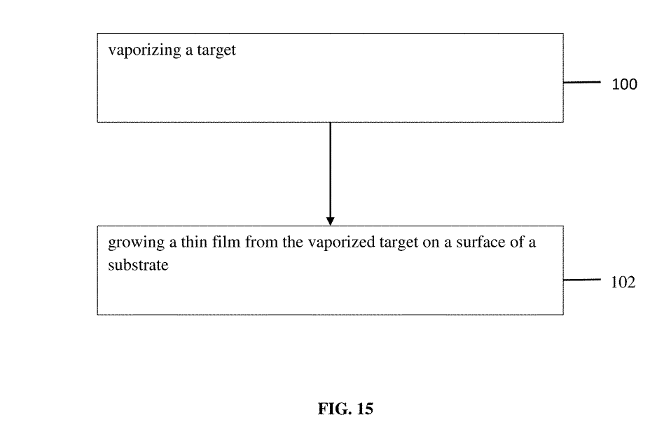

In another aspect, the present invention provides a method of making a ferroelectric thin film for a photoelectric device. The method comprises vaporizing a target 100 and growing a thin film from the vaporized target on a surface of a substrate 102 (FIG. 15). Such a grown thin film comprises a perovskite oxide ABO₃, and a doping agent selected from perovskites of Ba(Ni,Nb)O₃ and Ba(Ni,Nb)O_{3-δ} wherein δ is as defined above.

In some embodiments, the growing step 102 of the method uses a substrate having a temperature preferably in a range of from about 400 to about 800° C., or from about 420 to about 780° C., or from about 440 to about 760° C., or from about 460 to about 740° C., or from about 480 to about 720° C., or from about 500 to about 700° C., or from about 520 to about 680° C., or from about 540 to about 660° C., or from about 560 to about 640° C., or from about 580 to about 620° C., or from about 590 to about 610° C.

In some embodiments, the substrate in the growing step 102 is lattice mismatched with respect to the grown thin film.

In some embodiments, the vaporizing step 100 is performed using a laser, or radio-frequency magnetron (RF) sputtering.

In some embodiments, in the growing step 102, the substrate is subjected to a pressure preferably in the range of from about 0.1 mTorr to about 75 mTorr, or from about 0.5 mTorr to about 70 mTorr, or from about 1.0 mTorr to about 70 mTorr, or from about 2 mTorr to about 65 mTorr, or from about 3 mTorr to about 65 mTorr, or from about 5 mTorr to about 65 mTorr, or from about 5 mTorr to about 60 mTorr, or from about 7 mTorr to about 60 mTorr, or from about 10 mTorr to about 60 mTorr, or from about 10 mTorr to about 55 mTorr, or from about 12 mTorr to about 55 mTorr, or from about 15 mTorr to about 55 mTorr.

In some embodiments, the growth on perovskite STO(001) substrates is performed for different p(O₂)-T conditions in order to find the best growth conditions and determine the influence of these conditions on the growth process and the quality of the resultant thin film. The produced thin films are highly oriented. The best quality thin films may be obtained when p(O₂) is about 50 mTorr and the temperature is about 650-685° C. Therefore, for further experiments, 50 mTorr of O₂ pressure and 650° C. were chosen as the growth parameters sufficient for the crystallization of the thin film without much loss of potassium.

The substrate used in the method of the present invention preferably comprises a material selected from SrTiO₃, glass (SiO₂/Si(100)), DyScO₃, (La,Sr)(Al,Ta)O₃, MgO, ZrO₂, electrically conductive perovskite, metallic perovskite, Nb-doped SrTiO₃, electrically conductive film, metallic films, SrRuO₃, LaNiO₃ and non-perovskite oxides.

In some embodiments, the substrate comprises ABO₃ perovskites such as single-crystalline (001)-oriented SrTiO₃ or glass (SiO₂/Si(100)). Other materials such as a conducting metallic material of the bottom electrode may be included in a substrate such as Si of any common crystallographic orientation, e.g. (001), (110), (111). The BTNNO film may also be grown on substrates comprising electrically conductive or metallic perovskite, non-perovskite substrates such as Nb-doped SrTiO₃, electrically conductive or metallic films, perovskites such as SrRuO₃, LaNiO₃, and non-perovskite oxides, such as oxides of noble or transition metal elements or alloys.

In exemplary embodiments, the FE photovoltaic film may be grown on a substrate using a physical vapor deposition process such as pulsed laser deposition (PLD). The PLD process is typically not used to form thin films out of KBNNO due to the complexity and difficulties that are typically encountered in the formation of thin films having a composition such as KBNNO. However, the present invention provides a suitable process that can use PLD to produce FE thin films from the materials of the present invention for use in photovoltaic devices.

The PLD process is a process where a laser generating device transmits a pulsed laser beam inside a vacuum chamber to strike a target that comprises a material that is to be grown on a substrate. The power of the laser beam should be such that it causes vaporization of the target. The struck target is thereby vaporized and the vaporized material is deposited on the substrate to grow a thin film on the substrate.

The growth of thin films using the PLD process involves a complex process requiring control of a number of parameters relevant with the formation of the targets and the process of growing the FE material. Some of conditions include: (1) the composition of the targets; (2) the composition of the substrates on which the vaporized target material is to be grown; (3) the temperature at which the substrate is maintained during the process; (4) the power, frequency and wavelength of the laser used to strike the target; (5) the appropriate distance between the target and the substrate on which the vaporized target material would be grown; and (6) environmental factors surrounding the laser, target and substrate that would impact the growth of the target material on the substrate to form the thin film.

In one embodiment, the PLD process is performed with a KrF laser having a wavelength of 248 nm. The energy density of the laser was about 200 mJ and the laser frequency was 3-5 Hz. Depending on the environmental condition of the target and the energy needed to vaporize the target, the energy density of the laser may preferably be between about 10 mJ and about 10 J, or between about 100 mJ and about 900 mJ, or between about 100 mJ and about 800 mJ, or between about 200 mJ and about 800 mJ, or between about 200 mJ and about 700 mJ.

In this embodiment, the laser beam is focused on the target. The target may have 50 mol. % of KBNNO mixed with 50 mol. % of KNO₃. The distance between the target and the substrate may preferably be 1 to 15 cm, or 2 to 10 cm, or 4-8 cm, from 5 to 6 cm. The oxygen pressure is in a range of from 20 to 100 mTorr and the temperature of the substrate is in a range of from 600 to 700° C. Further, a 15 nm layer of a SrRuO₃ electrode may be deposited on top of the SrTiO₃ substrate (or SiO₂/Si(100) substrate) prior to the growth of the thin film on the substrate.

Other physical vapor deposition methods similar to PLD may also be used, such as RF sputtering. Further, thin films may also be formed via metalorganic chemical vapor or atomic layer deposition (ALD) from metalorganic precursors, such as tris (1-methoxy-2-methyl-2-propoxy)bismuth (Bi(mmp)₃), tris (2,2,6,6-tetramethyl-3,5-heptanedionato)bismuth(Bi(thd)₃) and Bi(N(Si(CH₃)₃)₂)₃. Other precursors may include potassium tert-butoxide and potassium-dipvaloylmethane pentaethoxyniobium. In ALD, initial deposition of the film may result in an amorphous structure, requiring subsequent annealing to form the correct thin film structure and stoichiometry. Also, the thin films may be formed using sol-gel methods involving metalorganic precursors.

The target may also be created using the PLD process, which involves a number of parameters to ensure that the final thin film is suitable for use in photovoltaic devices. It should be understood that the different processes for making the targets disclosed herein may be used in other vapor deposition methods, such as RF sputtering.

When making targets in accordance with the processes discussed above, to minimize absorption of H₂O, which may be an issue in the synthesis of KNbO₃, at all stages of the synthesis, targets may be either kept at an elevated temperature (at least 200° C.) or placed in a dessicator to minimize their exposure to moisture.

Also, when preparing pellets of [KNbO₃]₁₋ₓ [BaNi_{1/2}Nb_{1/2}O_{3-delta}]ₓ composition for use as targets, additional KNO₃ material may be added for correction to grow a final thin film with the appropriate composition. An exemplary stoichiometric ratio of the targets is the following, for x=0.1: (For K_{0.9}Ba_{0.1}Nb_{0.95}Ni_{0.05}O₃+KNO₃; KNO₃:Nb₂O₅:BaO:NiO=(1.9):(0.475):(0.1):(0.05). For Nb₂O₅, 0.95 is divided by 2 because Nb₂O₅ has 2 Nb per mole.

In producing the films of the present invention, the thickness of the final films will play a role in the optical absorption by the films and the depolarizing field that is associated with the FE polarization. Preferably, the thickness is such that these opposing qualities are counterbalanced. Particularly, as the thickness is reduced, the total amount of absorbed light is reduced, reducing the ultimate efficiency of conversion of light to photovoltage. On the other hand, as the film thickness is reduced, the beneficial effect of the depolarizing field, a finite potential difference acting across a thinner film, increases. Thus a selected value of film thickness for a given FE material and electrode materials, which also influences the depolarizing field, leads to an optimal film thickness value for desired power conversion efficiency by the photovoltaic cells.

The role played by K-deficient impurity phases in the K—Nb—O system that appear in the thin film as a result of its non-stoichiometry is due to potassium oxide evaporation during deposition. One of the main challenges for the growth of stoichiometric thin films is finding an efficient correction for potassium loss that may occur. To correct for potential potassium loss, KNO₃ may be added to the KBNNO pellet and the proper amount of KNO₃ needed for the deposition of stoichiometric thin films has been determined to preferably be from about 40 to about 60 mol. %, or from about 45 to about 55 mol. %, or from about 48 to about 52 mol. %.

A further factor that plays a role in the growth of thin films is the difference in lattice-parameters between the thin film and the substrate. The difference in the lattice-parameters, c, between the thin films with different thicknesses may be determined from the XRD patterns. This permits estimation of the tensile strain imposed by the substrate on the perovskite structure. The epitaxial strain is known to relax via the appearance of misfit dislocations that appear when the thin film reaches a certain thickness. To determine the epitaxial strain state of thin films, several thin films were produced with different thicknesses.

Table 4 shows the energy-dispersive X-ray analysis collected at 15 kV of a film obtained at optimized conditions using a heater. K:Nb ratio is close to 1:1. Ni presence is confirmed by later long-time collection of the spectrum. Ta impurity is the result of use of an impure precursor powder material.

TABLE 4
Energy-dispersive X-ray analysis FE films

| Element | Weight % | Atomic % |
|---|---|---|
| K K | 2.88 | 4.99 |
| Ta K | 31.62 | 44.80 |
| Ni K | 0.13 | 0.15 |
| Sr L | 57.86 | 44.81 |
| Nb L | 5.79 | 4.23 |
| Ru L | 0.95 | 0.64 |
| Ba L | 0.77 | 0.38 |

In some embodiments, a photovoltaic cell comprising the ferroelectric perovskite composition of the present invention is provided. Preferably, the ferroelectric perovskite composition is a thin film. The thin film preferably has a thickness of from about 15 nm to about 1 micron, or from about 30 nm to about 900 nm, or from about 50 nm to about 800 nm, from about 70 nm to about 700 nm, or from about 80 nm to about 600 nm, or from about 100 nm to about 500 nm.

It is to be understood, however, that even though numerous characteristics and advantages of the present invention have been set forth in the foregoing description, together with details of the method, composition and function of the invention, the disclosure is illustrative only, and changes may be made in detail, within the principles of the invention to the full extent indicated by the broad general meaning of the terms in which the appended claims are expressed.

The following examples are illustrative, but not limiting, of soft gel-mass capsules made by a process in accordance with the present disclosure. Other suitable modifications and adaptations of the variety of conditions and parameters normally encountered in the field, and which are obvious to those skilled in the art, are within the scope of the disclosure.

### EXAMPLES

### Example 1

### Ceramic Pellet Preparation

BTNNO ceramics were synthesized by standard solid-state synthesis methods. Pre-dried BaCO₃, TiO₂, NiO and Nb₂O₅ powders were weighed in stoichiometric amounts and mixed by ball-milling with yttria-stabilized zirconia grinding media in ethanol for 6 h. After drying, the mixtures were calcined on platinum foil in an alumina crucible at 1000° C. for 12 h. The calcined powders were ball-milled again for 20 h to promote homogeneity and sinterability before being pressed into 3-mm thick, 8-mm diameter pellets in a uniaxial press. The pellets were then sintered at temperatures between 1350° C. and 1450° C., depending on the composition, for 5 h. During sintering, the pellets were placed on a platinum foil in an alumina crucible and surrounded by sacrificial powder of the same composition. One of the produced compositions, wherein x=0.1, namely, (1-x)BaTiO₃-xBa(Ni_{0.5}Nb_{0.5})O_{2.75}, was further annealed at 1100° C. for 20 h after sintering to achieve true thermodynamic equilibrium.

The targets for PLD were synthesized in the same manner with a die of 1-inch diameter. The sintered pellets were ground into fine powders for powder XRD and diffuse reflectance spectra. Powder XRD patterns of the samples were collected on a laboratory X-ray diffractometer (Rigaku GiegerFlex D/Max-B) using Cu Kα radiation generated at 45 kV and 30 mA. Diffuse reflectance spectra were collected on a Cary 5000 UV-Vis spectrophotometer with the Praying Mantis diffuse reflectance accessory. All sample spectra were acquired with respect to a powdered MgO baseline.

### Example 2

### BTNNO Film Growth

BTNNO films were grown from stoichiometric lab-prepared BTNNO targets by PLD onto single-crystal (001) Nb:SrTiO₃ substrates (MTI Corporation, Richmond Calif.) with a laser repetition rate of 3-5 Hz. The substrate was heated to 650° C. under an oxygen pressure of 30 mTorr. The film growth rate was about 0.15 Å/pulse. The La_{0.7}Sr_{0.3}MnO₃ bottom electrode was grown at 730° C. under 150 mTorr of oxygen pressure. The laser repetition rate was 5 Hz.

### Example 3

### BTNNO Film Characterization

The stoichiometry and morphology of the BTNNO films was studied with a scanning electron microscope (Zeiss Supra 50VP) equipped with an energy-dispersive X-ray spectroscopy (EDS) system. XRD of the films was performed with a 4-circle X-ray diffractometer (Rigaku Smartlab, 40 kV, 44 mA, Cu Kα) equipped with a double (220)Ge monochromator in a parallel beam geometry. RSM's were collected with a PANalytical X'Pert diffractometer (40 kV, 45 mA, Cu Kα) equipped with a two-bounce monochromator and a two-dimensional detector. TEM specimen preparation was performed with a dual-beam focused ion beam SEM (FEI Strata DB235). Bright-field imaging was conducted with a JEOL 2100 TEM operated at 200 kV.

XPS spectra were collected (PHI Versa 5000) from the pre-cleaned film surface (0.5 keV, 1 mA, 60 s) with 15-keV photons incident in the direction perpendicular to the film surface to improve the collection depth (pass energies were 11.75 eV for BaTiO₃ and 23.5 eV for BTNNO, 0.05 eV step size, 100×100 μm² area of collection). The measurements were collected on films deposited on conducting Nb:SrTiO₃ to minimize surface charging.

Semi-transparent electrodes consisting of Au and indium tin oxide film layers were prepared by shadow-masked vacuum deposition. An Au layer (about 5 nm thick) was thermally evaporated under high vacuum (base pressure 10⁻⁷ Torr) through a shadow mask (85×85 μm² in area), after which an indium tin oxide layer (about 200 nm thick) was grown by PLD at 200° C. (p(O₂)=30-50 mTorr) also through the same shadow mask.

Switching of ferroelectric polarization was measured with a commercial ferroelectric tester (Radiant Technologies, Inc) at 100 and 200 Hz with time dependent-component filtering at 77-400 K in high vacuum (10⁻⁶ torr, Lakeshore Cryotronics, Model TTP4). Steady-state photocurrent/bias-voltage traces were collected with 405 nm and 532 nm wavelength solid state lasers under vacuum and alternately under ambient pressure with a picoammeter (Keithley, Model 6487) and a semiconductor parameter analyzer (Keithley, Model 4200-SCS).

What is claimed is:

1. A ferroelectric perovskite composition, comprising:
a. a perovskite oxide ABO₃; and
b. a doping agent selected from perovskites of Ba(Ni,Nb)O₃ and Ba(Ni,Nb)O_{3-δ} wherein δ is in a range of from 0 to 0.1.

2. The ferroelectric perovskite composition of claim 1, wherein the composition is represented by a formula: xBa(Ni,Nb)O₃.(1-x)ABO₃ or xBa(Ni,Nb)O_{3-δ}.(1-x)ABO₃, x is in a range from about 0.01 to about 0.5, δ is in a range of from about 0 to about 0.1.

3. The ferroelectric perovskite composition of claim 1, wherein the ABO₃perovskite oxide comprises BaTiO₃.

4. The ferroelectric perovskite composition of claim 1, wherein the composition has an atomic content of Ni in a range from about 0.005% to about 0.1%.

5. The ferroelectric perovskite composition of claim 1, wherein the composition has a band gap in a range of from about 0.8 eV to about 3.1 eV.

6. The ferroelectric perovskite composition of claim 1, wherein the composition exhibits a measurable absorption of greater than about 104 cm⁻¹, throughout the entire visible wavelength spectrum.

7. The ferroelectric perovskite composition of claim 1, wherein the composition exhibits ferroelectric switching at a temperature up to about 300 K.

8. The ferroelectric perovskite composition of claim 1, wherein the composition exhibits a photovoltaic effect with a measurable, non-zero open-circuit voltage and a measurable, non-zero short-circuit current.

9. The ferroelectric perovskite composition of claim 8, wherein the photovoltaic effect is represented by reversing the polarity of current of the photovoltaic effect after electrical poling in an opposite film plane-normal direction.

10. The ferroelectric perovskite composition of claim 1, wherein the composition is in a form selected from ceramic, crystalline, and a film.

11. The ferroelectric perovskite composition of claim 10, wherein the composition is a film with a thickness in a range of from about 1 nm to about 10,000 nm.

12. The ferroelectric perovskite composition of claim 9, wherein the composition is a film having a band gap in a range of from about 0.8 eV to about 3.1 eV.

13. A method of making a ferroelectric thin film for a photoelectric device comprising:
vaporizing a target, and
growing a thin film from the vaporized target on a surface of a substrate, wherein the grown thin film comprises:
a. a perovskite oxide ABO₃; and
b. a doping agent selected from perovskites of Ba(Ni,Nb)O₃ and Ba(Ni,Nb)O_{3-δ} wherein _{δ} is in a range of from 0 to 0.1.

14. The method of claim 13, wherein during said growing step the substrate has a temperature in a range of from about 400 to about 800° C.

15. The method of claim 13, wherein the substrate is lattice mismatched with respect to the grown thin film.

16. The method of claim 13, wherein the vaporizing step is performed using a laser or RF sputtering.

17. The method of claim 13, wherein the substrate is subjected to a pressure in a range of from about 0.1 mTorr to about 75 mTorr.

18. The method of claim 13, wherein the substrate comprises a material selected from the group consisting of SrTiO_{3,} glass (SiO₂/Si(100)), DyScO3, (La,Sr)(Al,Ta)O₃, MgO, ZrO₂, electrically conductive perovskite, metallic perovskite, Nb-doped SrTiO₃, electrically conductive film, metallic films, SrRuO₃, LaNiO₃ and non-perovskite oxides.

19. A photovoltaic cell comprising the ferroelectric perovskite composition of claim 1.

20. The photovoltaic cell of claim 19, wherein the ferroelectric perovskite composition is a film.

21. The photovoltaic cell of claim 20, wherein the film has a thickness in a range of from about 1 nm to about 10,000 nm
